(19) United States
(12) Patent Application Publication
(10) Pub. No.: US 2025/0266382 A1
(43) Pub. Date: Aug. 21, 2025

(54) SEMICONDUCTOR DEVICE AND METHOD OF MANUFACTURING THE SAME

(71) Applicant: Kioxia Corporation, Tokyo (JP)

(72) Inventors: Hiroyuki YAMASAKI, Nagoya Aichi (JP); Yasuaki NAKATA, Kuwana Mie (JP); Masayoshi TAGAMI, Kuwana Mie (JP)

(73) Assignee: Kioxia Corporation, Tokyo (JP)

(21) Appl. No.: 18/823,711

(22) Filed: Sep. 4, 2024

(30) Foreign Application Priority Data
Feb. 15, 2024 (JP) 2024-021358

(51) Int. Cl. H01L 23/00; H10B 41/10; H10B 41/20; H10B 43/10; H10B 43/20

(52) U.S. Cl. CPC H01L 24/08; H10B 41/10; H10B 41/20; H10B 43/10; H10B 43/20; H01L 2224/08146

(57) ABSTRACT

In one embodiment, a semiconductor device includes a first insulator, a first plug provided in the first insulator, and a first interconnect layer provided on the first insulator. The device further includes a second insulator including a first region that is provided on the first insulator and includes a first upper face, and a second region that is provided on the first interconnect layer and includes a second upper face higher than the first upper face. The device further includes a second interconnect layer including a first portion that is provided on the first insulator and the first plug, a second portion that is provided on the first region, and a third portion that is provided on the second region, the second interconnect layer further including a bonding pad.

### CROSS REFERENCE TO RELATED APPLICATIONS

This application is based upon and claims the benefit of priority from the prior Japanese Patent Application No. 2024-021358, filed on Feb. 15, 2024, the entire contents of which are incorporated herein by reference.

### FIELD

Embodiments described herein relate to a semiconductor device and a method of manufacturing the same.

### BACKGROUND

When an interconnect layer including a bonding pad is disposed on a plug, failure may occur to the plug after the interconnect layer is formed. For example, the plug may be damaged when the bonding pad is contacted with a probe needle.

### BRIEF DESCRIPTION OF THE DRAWINGS

FIG. 1 is a cross-sectional view illustrating the structure of a semiconductor device of a first embodiment;

FIG. 2 is an enlarged cross-sectional view illustrating the structure of the semiconductor device of the first embodiment;

FIGS. 3 to 6 are cross-sectional views illustrating a method of manufacturing the semiconductor device of the first embodiment;

FIG. 7 is a cross-sectional view illustrating the structure of the semiconductor device of the first embodiment;

FIGS. 8 to 10 are cross-sectional views illustrating the method of manufacturing the semiconductor device of the first embodiment;

FIGS. 11 and 12 are cross-sectional views illustrating a method of manufacturing a semiconductor device of a first comparative example of the first embodiment;

FIGS. 13 and 14 are cross-sectional views illustrating a method of manufacturing a semiconductor device of a first modification of the first embodiment;

FIG. 15 is a plan view illustrating the structure of the semiconductor device of the first embodiment;

FIGS. 16A to 18D are plan views illustrating various examples of the structure of the semiconductor device of the first embodiment;

FIGS. 19A to 22B are cross-sectional views illustrating the method of manufacturing the semiconductor device of the first embodiment;

FIGS. 23A and 23B are cross-sectional views illustrating the method of manufacturing the semiconductor device of the first comparative example of the first embodiment;

FIGS. 24A and 24B are cross-sectional views illustrating the method of manufacturing the semiconductor device of the first embodiment;

FIGS. 25A to 26B are cross-sectional views illustrating a first example of the method of manufacturing the semiconductor device of the first embodiment;

FIGS. 27A to 28B are cross-sectional views illustrating a second example of the method of manufacturing the semiconductor device of the first embodiment;

FIG. 29 is a cross-sectional view illustrating the structure of a semiconductor device of a second modification of the first embodiment;

FIG. 30 is a cross-sectional view illustrating the structure of a semiconductor device of a third modification of the first embodiment;

FIG. 31 is a cross-sectional view illustrating the structure of a semiconductor device of a fourth modification of the first embodiment;

FIG. 32 is a cross-sectional view illustrating the structure of a semiconductor device of a fifth modification of the first embodiment;

FIG. 33 is a cross-sectional view illustrating the structure of a semiconductor device of a sixth modification of the first embodiment;

FIG. 34 is a cross-sectional view illustrating the structure of a semiconductor device of a seventh modification of the first embodiment;

FIG. 35 is a cross-sectional view illustrating the structure of a semiconductor device of an eighth modification of the first embodiment;

FIG. 36 is a cross-sectional view illustrating the structure of a semiconductor device of a ninth modification of the first embodiment;

FIGS. 37A to 37C are plan views and a cross-sectional view illustrating the structure of a semiconductor device of a second embodiment;

FIGS. 38A to 38C are plan views and a cross-sectional view illustrating the structure of a semiconductor device of a first comparative example of the second embodiment;

FIGS. 39A and 39B are cross-sectional views for comparing the semiconductor device of the second embodiment and the semiconductor device of the first comparative example of the second embodiment;

FIGS. 40A and 40B are a plan view and a cross-sectional view illustrating the structure of a semiconductor device of a first modification of the second embodiment;

FIGS. 41A and 41B are a plan view and a cross-sectional view illustrating the structure of a semiconductor device of a second modification of the second embodiment;

FIGS. 42A and 42B are a plan view and a cross-sectional view illustrating the structure of a semiconductor device of a third modification of the second embodiment;

FIGS. 43A and 43B are a plan view and a cross-sectional view illustrating the structure of a semiconductor device of a fourth modification of the second embodiment;

FIGS. 44A and 44B are cross-sectional views illustrating the structures of semiconductor devices of a fifth modification and a sixth modification of the second embodiment;

FIGS. 45A and 45B are a plan view and a cross-sectional view illustrating the structure of a semiconductor device of a seventh modification of the second embodiment;

FIGS. 46A and 46B are a plan view and a cross-sectional view illustrating the structure of a semiconductor device of an eighth modification of the second embodiment;

FIGS. 47A and 47B are a plan view and a cross-sectional view illustrating the structure of a semiconductor device of a ninth modification of the second embodiment;

FIGS. 48A and 48B are a plan view and a cross-sectional view illustrating the structure of a semiconductor device of a tenth modification of the second embodiment; and

FIGS. 49A and 49B are cross-sectional views illustrating the structures of semiconductor devices of an eleventh modification and a twelfth modification of the second embodiment.

### DETAILED DESCRIPTION

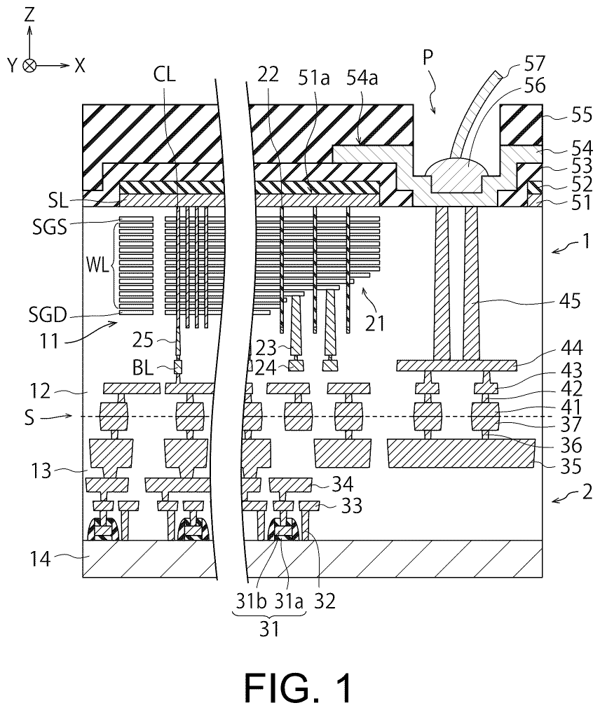

Embodiments will now be explained with reference to the accompanying drawings. In FIGS. 1 to 49B, identical components are denoted by the same reference sign, and duplicate description thereof is omitted.

In one embodiment, a semiconductor device includes a first insulator, a first plug provided in the first insulator, and a first interconnect layer provided on the first insulator. The device further includes a second insulator including a first region that is provided on the first insulator and includes a first upper face, and a second region that is provided on the first interconnect layer and includes a second upper face higher than the first upper face. The device further includes a second interconnect layer including a first portion that is provided on the first insulator and the first plug, a second portion that is provided on the first region, and a third portion that is provided on the second region, the second interconnect layer further including a bonding pad.

### First Embodiment

FIG. 1 is a cross-sectional view illustrating the structure of a semiconductor device of a first embodiment.

The semiconductor device of the present embodiment includes, for example, a three-dimensional semiconductor memory. As described later, the semiconductor device of the present embodiment is manufactured by bonding an array wafer including an array chip 1, and a circuit wafer including a circuit chip 2.

The array chip 1 includes a memory cell array 11 including a plurality of memory cells, and an inter layer dielectric 12 below the memory cell array 11. The inter layer dielectric 12 is, for example, a multilayer film including a silicon oxide film (SiO₂ film) and any other insulator. The inter layer dielectric 12 is an example of the first insulator.

The circuit chip 2 is provided below the array chip 1. FIG. 1 illustrates a bonding face S of the array chip 1 and the circuit chip 2. The circuit chip 2 includes an inter layer dielectric 13 below the inter layer dielectric 12, and a substrate 14 below the inter layer dielectric 13. The inter layer dielectric 13 is, for example, a multilayer film including a SiO₂ film and any other insulator. The substrate 14 is, for example, a semiconductor substrate such as a silicon (Si) substrate. The substrate 14 is an example of a first substrate.

FIG. 1 illustrates X and Y directions parallel to the surface of the substrate 14 and orthogonal to each other, and a Z direction orthogonal to the surface of the substrate 14. The X, Y, and Z directions intersect each other. In the present specification, the positive Z direction is treated as the upward direction, and the negative Z direction is treated as the downward direction. The negative Z direction may be or may not be aligned with the direction of gravity.

The array chip 1 includes a plurality of word lines WL, a source side select line SGS, and a drain side select line SGD as a plurality of electrode layers in the memory cell array 11. The source side select line SGS is disposed above the word lines WL, and the drain side select line SGD is disposed below the word lines WL. The memory cell array 11 includes a plurality of columnar portions CL penetrating through the word lines WL, the source side select line SGS, and the drain side select line SGD. The columnar portions CL extend in the Z direction.

FIG. 1 illustrates a staircase structure portion 21 in the memory cell array 11, and a plurality of beam portions 22 provided in the staircase structure portion 21. The beam portions 22 extend in the Z direction. Each word line WL is electrically connected to a word interconnect layer 24 through a contact plug 23. Each columnar portion CL is electrically connected to a bit line BL through a via plug 25 and electrically connected to a source line SL. The source line SL is provided above the source side select line SGS, and the bit line BL is provided below the drain side select line SGD. The source line SL is provided on the columnar portions CL in contact with the columnar portions CL. The source line SL is a portion of the memory cell array 11.

The circuit chip 2 further includes a plurality of transistors 31, a plurality of contact plugs 32, an interconnect layer 33, an interconnect layer 34, an interconnect layer 35, a plurality of via plugs 36, and a plurality of metal pads 37 in the inter layer dielectric 13.

Each transistor 31 includes a gate insulator 31a and a gate electrode 31b provided in order on the substrate 14, and a source region and a drain region (not illustrated) provided in the substrate 14. Each contact plug 32 is provided on the gate electrode 31b, the source region, or the drain region of the corresponding transistor 31. The interconnect layer 33 is provided on the contact plugs 32 and includes a plurality of interconnects. The interconnect layer 34 is provided on the interconnect 35 layer 33 and includes a plurality of interconnects. The interconnect layer is provided on the interconnect layer 34 and includes a plurality of interconnects. The via plugs 36 are provided on the interconnect layer 35. The metal pads 37 are provided on the via plugs 36. The metal pads 37 are, for example, a metal layer including a copper (Cu) layer. The circuit chip 2 functions as a circuit that controls operation of the array chip 1. The circuit is constituted by the transistors 31 and the like and electrically connected to the metal pads 37.

The array chip 1 further includes a plurality of metal pads 41, a plurality of via plugs 42, an interconnect layer 43, an interconnect layer 44, and a plurality of via plugs 45 in the inter layer dielectric 12. The via plugs 45 are examples of first and second plugs.

The metal pads 41 are provided on the metal pads 37. The metal pads 41 are, for example, a metal layer including a Cu layer. The above-described circuit is electrically connected to the memory cell array 11 through the metal pads 37 and 41 and the like and controls operation of the memory cell array 11 through the metal pads 37 and 41 and the like. The via plugs 42 are provided on the metal pads 41. The interconnect layer 43 is provided on the via plugs 42 and includes a plurality of interconnects. The interconnect layer 44 is provided on the interconnect layer 43 and includes a plurality of interconnects. The above-described bit line BL is included in the interconnect layer 44. The via plugs 45 are provided on the interconnect layer 44. The via plugs 45 are, for example, metals plug including a tungsten (W) layer.

The array chip 1 further includes an interconnect layer 51, an insulator 52, an insulator 53, an interconnect layer 54, a passivation insulator 55, a solder 56, and a bonding wire 57 on the inter layer dielectric 12. The interconnect layer 51 is an example of the first interconnect layer. The insulator 53 is an example of the second insulator. The interconnect layer 54 is an example of the second interconnect layer.

The interconnect layer 51 is disposed on the inter layer dielectric 12 and disposed above the source side select line SGS. The interconnect layer 51 is, for example, a metal layer including a W layer. The interconnect layer 51 includes a plurality of interconnects such as an interconnect 51a. The interconnect 51a is provided on the above-described columnar portions CL and electrically connected to the columnar portions CL. The interconnect 51a is the above-described source line SL. At least a portion of the interconnect layer 51 may be a semiconductor layer such as a polysilicon layer.

The insulator 52 is formed on the interconnect layer 51. The insulator 52 is, for example, a multilayer film including a plurality of insulators.

The insulator 53 is formed on the inter layer dielectric 12, the interconnect layer 51, and the insulator 52. The insulator 53 is, for example, a SiO₂ film.

The interconnect layer 54 is formed on the inter layer dielectric 12 via the interconnect layer 51, the insulator 52, and the insulator 53. The interconnect layer 54 is, for example, a metal layer including an aluminum (Al) layer. The interconnect layer 54 includes a plurality of interconnects such as an interconnect 54a. The interconnect 54a is disposed on the inter layer dielectric 12, the via plugs 45, and the insulator 53 and electrically connected to the via plugs 45. A portion of the interconnect 54a functions as an external connection pad (bonding pad) of the semiconductor device of the present embodiment.

The passivation insulator 55 is formed on the insulator 53 and the interconnect layer 54 and includes an opening P where the surface of the interconnect 54a is exposed. An exposed portion of the interconnect 54a at the opening P functions as the above-described external connection pad. The interconnect 54a is connectable to a mounting substrate or another device by a bonding wire, a solder ball, a metal bump, or the like through the opening P. FIG. 1 illustrates the bonding wire 57 electrically connected to the interconnect 54a (bonding pad) by the solder 56. The passivation insulator 55 is, for example, a multilayer film including a SiO₂ film and a silicon nitride film (SiN film).

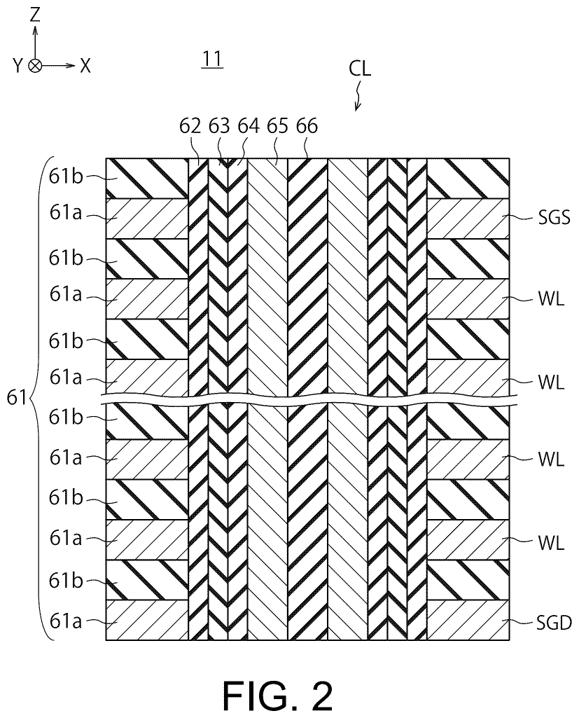

FIG. 2 is an enlarged cross-sectional view illustrating the structure of the semiconductor device of the first embodiment.

FIG. 2 illustrates the memory cell array 11 illustrated in FIG. 1. The memory cell array 11 includes a multilayer film 61 including a plurality of electrode layers 61a and a plurality of insulators 61b alternately stacked in the Z direction. The electrode layers 61a are separated from each other in the Z direction. Each electrode layer 61a functions as, for example, the above-described word lines WL, source side select line SGS, or drain side select line SGD. In FIG. 2, the uppermost electrode layer 61a is the source side select line SGS, the lowermost electrode layer 61a is the drain side select line SGD, and the other electrode layers 61a are the word lines WL. Each electrode layer 61a is, for example, a metal layer including a W layer. Each insulator 61b is, for example, a SiO₂ film.

FIG. 2 further illustrates one of the plurality of columnar portions CL illustrated in FIG. 1. Each columnar portion CL is provided in the multilayer film 61 and has a column shape extending in the Z direction. Each columnar portion CL includes a block insulator 62 provided on a side face of the multilayer film 61, an electric charge accumulation layer 63 provided on a side face of the block insulator 62, a tunnel insulator 64 provided on a side face of the electric charge accumulation layer 63, a channel semiconductor layer 65 provided on a side face of the tunnel insulator 64, and a core insulator 66 provided on a side face of the channel semiconductor layer 65. Each columnar portion CL constitutes a cell transistor (memory cell) with the word lines WL, constitutes a source side select transistor with the source side select line SGS, and constitutes a drain side select transistor with the drain side select line SGD.

The block insulator 62 is, for example, a SiO₂ film. The electric charge accumulation layer 63 is, for example, an insulator such as a SiN film. The electric charge accumulation layer 63 may be a semiconductor layer such as a polysilicon layer. The electric charge accumulation layer 63 can accumulate signal electric charge of the three-dimensional semiconductor memory. The tunnel insulator 64 is, for example, a SiO₂ film or a silicon oxynitride film (SiON film). The channel semiconductor layer 65 is, for example, a polysilicon layer. The channel semiconductor layer 65 functions as a channel of the three-dimensional semiconductor memory. The core insulator 66 is, for example, a SiO₂ film.

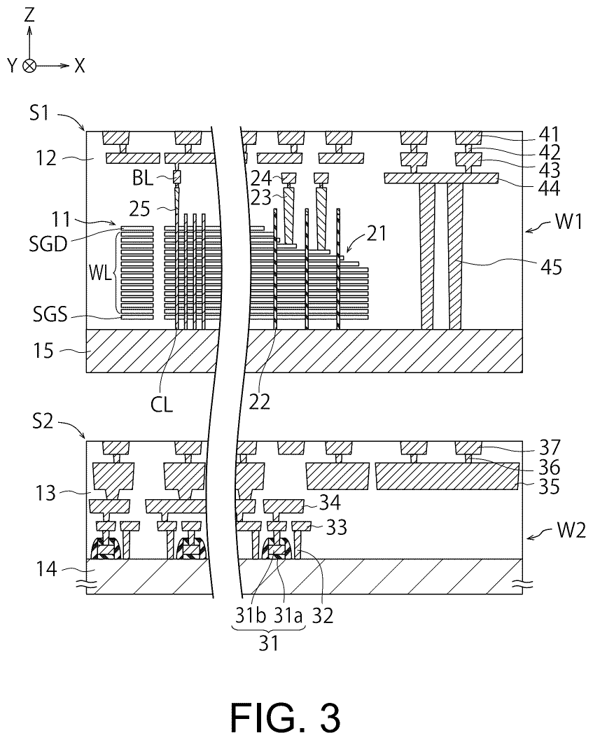

FIGS. 3 to 6 are cross-sectional views illustrating a method of manufacturing the semiconductor device of the first embodiment.

FIG. 3 illustrates an array wafer W1 including a plurality of array chips 1, and a circuit wafer W2 including a plurality of circuit chips 2. The orientation of the array wafer W1 in FIG. 3 is opposite the orientation of the array chip 1 in FIG. 1. In the present embodiment, a semiconductor device is manufactured by bonding the array wafer W1 and the circuit wafer W2. FIG. 3 illustrates the array wafer W1 before its orientation is inverted for bonding, and FIG. 1 illustrates an array chip 1 after bonded and diced with its orientation inverted for bonding.

FIG. 3 further illustrates an upper face S1 of the array wafer W1 and an upper face S2 of the circuit wafer W2. The array wafer W1 includes a substrate 15 below the memory cell array 11.

The substrate 15 is, for example, a semiconductor substrate such as a Si substrate.

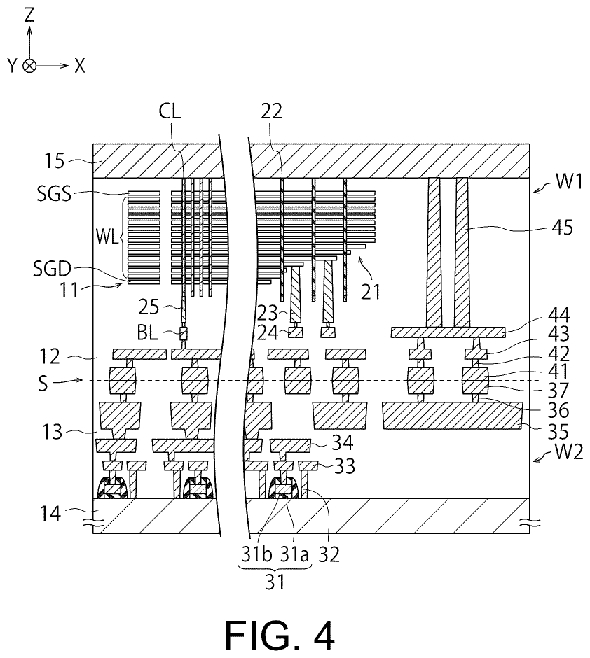

In the present embodiment, first, as illustrated in FIG. 3, the memory cell array 11, the inter layer dielectric 12, the staircase structure portion 21, the metal pads 41, the via plugs 45, and the like are formed on the substrate 15 of the array wafer W1, and the inter layer dielectric 13, the transistors 31, the contact plugs 32, the metal pads 37, and the like are formed on the substrate 14 of the circuit wafer W2. Subsequently, as illustrated in FIG. 4, the array wafer W1 and the circuit wafer W2 are bonded by mechanical pressure such that the upper face S1 and the upper face S2 face each other. Accordingly, the inter layer dielectric 12 and the inter layer dielectric 13 are bonded. Subsequently, the array wafer W1 and the circuit wafer W2 are annealed. Accordingly, the metal pads 41 are joined to the metal pads 37. In this manner, the substrate 15 and the substrate 14 are bonded with the inter layer dielectrics 12 and 13 sandwiched therebetween such that the memory cell array 11, the via plugs 45, and the like are formed (disposed) above the substrate 14.

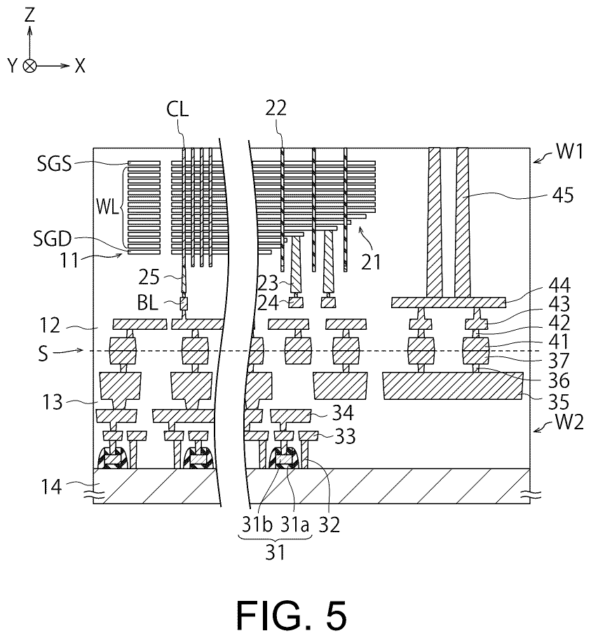

Subsequently, the substrate 15 is removed by chemical mechanical polishing (CMP) and/or wet etching (FIG. 5). Accordingly, the inter layer dielectric 12, the columnar portions CL, the beam portions 22, the via plugs 45, and the like are exposed.

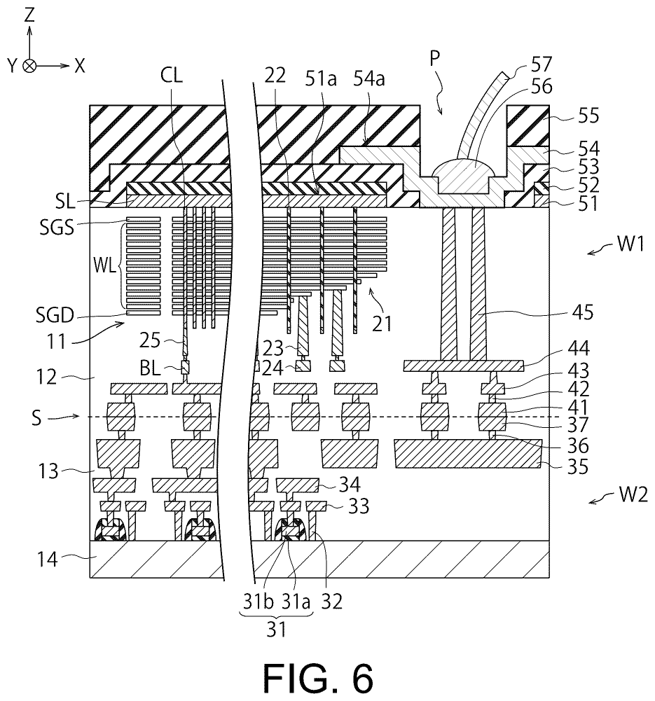

Subsequently, the interconnect layer 51, the insulator 52, the insulator 53, the interconnect layer 54, and the passivation insulator 55 are sequentially formed on the inter layer dielectric 12, the columnar portions CL, the beam portions 22, and the via plugs 45 (FIG. 6). The interconnect 51a (source line SL) in the interconnect layer 51 is formed on the columnar portions CL and the beam portions 22. The interconnect 54a in the interconnect layer 54 is formed on the inter layer dielectric 12, the via plugs 45, and the insulator 53 and exposed in the opening P of the passivation insulator 55. Subsequently, the substrate 14 is thinned by CMP and/or wet etching, the array wafer W1 and the circuit wafer W2 are cut into a plurality of chips, and then the bonding wire 57 is electrically connected to the interconnect 54a (bonding pad) by the solder 56 (FIG. 6). In this manner, the semiconductor device illustrated in FIG. 1 is manufactured.

Although FIG. 1 illustrates a boundary face of the inter layer dielectric 12 and the inter layer dielectric 13 and a boundary face of the metal pads 41 and the metal pads 37, these boundary faces are typically not observed after the above-described annealing. However, positions where these boundary faces exited can be estimated by detecting, for example, tilts of side faces of the metal pads 41 and side faces of the metal pads 37, or positional shift between the side faces of the metal pads 41 and the side faces of the metal pads 37.

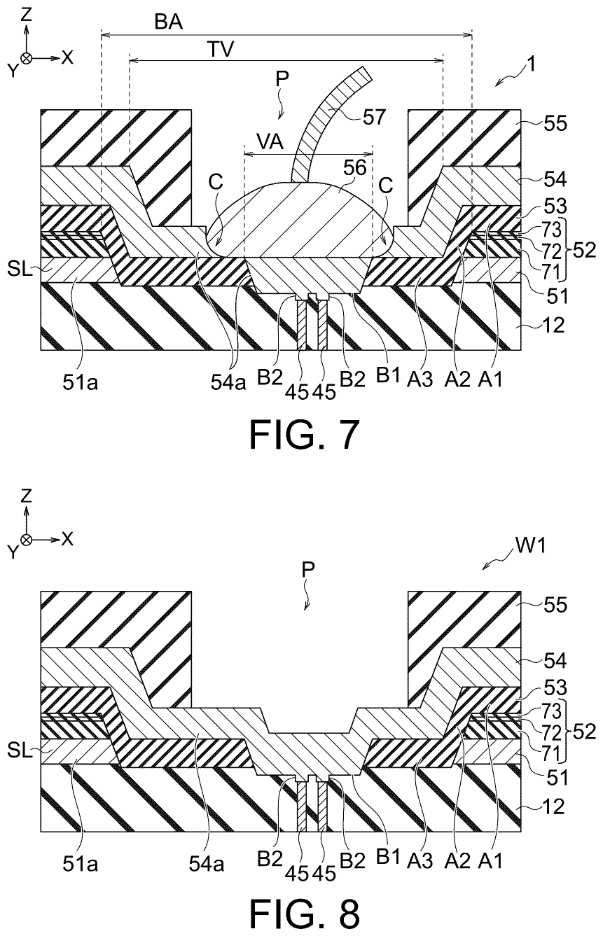

FIG. 7 is a cross-sectional view illustrating the structure of the semiconductor device of the first embodiment.

FIG. 7 illustrates a part of FIG. 1 in an enlarged manner.

Specifically, FIG. 7 illustrates the inter layer dielectric 12, the interconnect layer 51, the insulator 52, the insulator 53, the interconnect layer 54, the passivation insulator 55, the solder 56, and the bonding wire 57.

The interconnect layer 51 and the insulator 52 are formed in order on the inter layer dielectric 12. The insulator 52 includes an insulator 71 formed on the interconnect layer 51, an insulator 72 formed on the insulator 71, and an insulator 73 formed on the insulator 72.

The insulator 53 includes a region A1 formed on the interconnect layer 51 via the insulator 52, a region A2 formed on side faces of the interconnect layer 51 and the insulator 52, and a region A3 formed on the inter layer dielectric 12. As described later, the insulator 53 is formed on the inter layer dielectric 12, the interconnect layer 51, and the insulator 52 after the interconnect layer 51 and the insulator 52 are formed on the inter layer dielectric 12 and a portion of the interconnect layer 51 and the insulator 52 is removed by etching. As a result, the insulator 53 includes not only the region A1 but also the regions A2 and A3. The upper face of the region A1 is higher than the upper face of the region A3. The region A3 is an example of a first region having a first upper face. The region A1 is an example of a second region having a second upper face.

The interconnect layer 54 is formed on the inter layer dielectric 12 via the interconnect layer 51, the insulator 52, and the insulator 53. As described later, the interconnect layer 54 is formed on the inter layer dielectric 12, the via plugs 45, and the insulator 53 after the insulator 53 is formed and a portion of the insulator 53 is removed by etching. As a result, the interconnect 54a illustrated in FIG. 7 includes a portion formed on the inter layer dielectric 12 and the via plugs 45, a portion formed on the region A3 of the insulator 53, and a portion formed on the region A1 of the insulator 53. The portion on the inter layer dielectric 12 and the via plugs 45 is an example of a first portion. The portion on the region A3 of the insulator 53 is an example of a second portion. The portion on the region A1 of the insulator 53 is an example of a third portion. In FIG. 7, the upper face of the second portion is higher than the upper face of the first portion, and the upper face of the third portion is higher than the upper face of the second portion.

The portion of the interconnect 54a on the inter layer dielectric 12 and the via plugs 45 includes a portion B1 provided on the inter layer dielectric 12, and a plurality of portions B2 protruding downward from the portion B1. Each portion B2 is provided on one corresponding via plug 45. In FIG. 7, the left portion B2 is provided on the left via plug 45, the right portion B2 is provided on the right via plug 45, and the portions B2 are separated from each other. The height of the upper end (upper face) of each via plug 45, in other words, the height of the lower face of each portion B2 is lower than the height of the lower face of the portion B1. The portion B1 is an example of an upper portion. The portions B2 are an example of lower portions (first and second lower portions). In FIG. 7, each portion B2 is provided on the one corresponding via plug 45 and on the inter layer dielectric 12 around the via plug 45.

In FIG. 7, the interconnect 54a (bonding pad) is formed with a probe mark C. The probe mark C illustrated in FIG. 7 is formed at the boundary between the portion (first portion) of the interconnect 54a on the inter layer dielectric 12 and the portion (second portion) of the interconnect 54a on the region A3. As described later, the probe mark C is formed when the bonding pad is contacted with a probe needle to examine the semiconductor device of the present embodiment. The first and second portions of the interconnect 54a may be separated from each other by the probe mark C or may be connected to each other at portions other than the probe mark C. In a case where the first and second portions are separated from each other by the probe mark C, the first and second portions are electrically connected to each other by the solder 56.

In the present embodiment, an opening is formed in the interconnect layer 51 and the insulator 52, and a portion of the insulator 53 is formed in the opening. FIG. 7 illustrates a region BA where the opening is formed. The insulator 53 has a shape recessed in the region BA, and accordingly, the interconnect layer 54 has a shape recessed in a region TV. In the present embodiment, another opening is formed in the insulator 53, and a portion of the interconnect layer 54 is formed in the opening. FIG. 7 illustrates a region VA where the opening is formed. The region A3 and the like of the insulator 53 are included in the region BA, the second portion and the like of the interconnect layer 54 are included in the region TV, and the first portion and the like of the interconnect layer 54 are included in the region VA. Further details of the regions BA, TV, and VA will be described later.

FIGS. 8 to 10 are cross-sectional views illustrating the method of manufacturing the semiconductor device of the first embodiment. FIGS. 8 to 10 illustrate processes of forming the structure illustrated in FIG. 7.

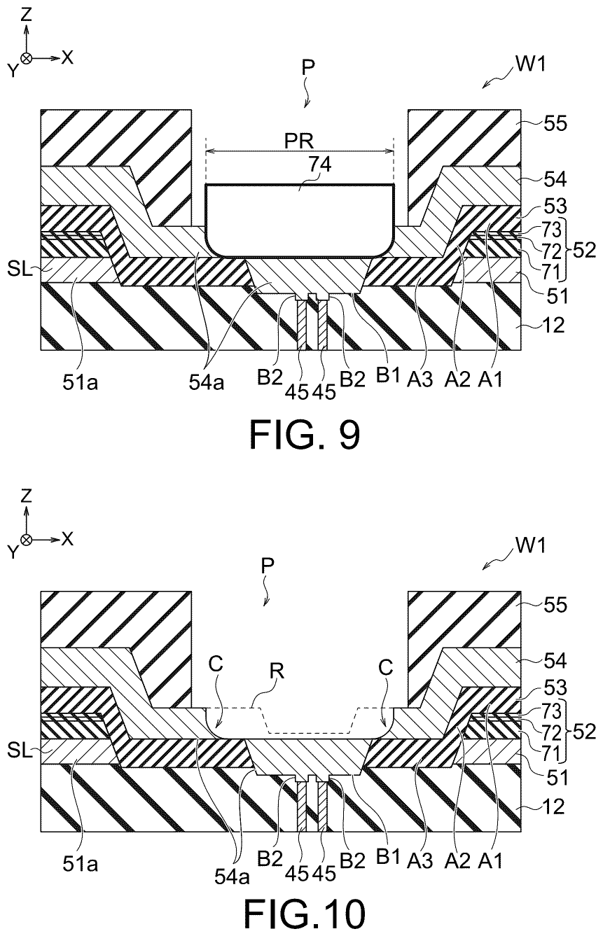

First, the interconnect layer 51, the insulator 52, the insulator 53, the interconnect layer 54, and the passivation insulator 55 are formed on the inter layer dielectric 12 (FIG. 8). Subsequently, the interconnect 54a (bonding pad) is contacted with a probe needle 74 to examine the semiconductor device of the present embodiment (FIG. 9). As a result, the interconnect 54a in a region R is pressed by the probe needle 74, and the interconnect 54a is formed with the probe mark C (FIG. 10). Thereafter, the bonding wire 57 is electrically connected to the interconnect 54a by the solder 56.

FIG. 9 illustrates a width PR of the probe needle 74 in the X direction. In the present embodiment, the width PR of the probe needle 74 is shorter than the width of the opening P of the passivation insulator 55 in the X direction. This makes it possible to insert the probe needle 74 into the opening P. Moreover, in the present embodiment, the width PR of the probe needle 74 is longer than the width of the portions B1 and B2 (first portion) of the interconnect 54a in the X direction. This makes it possible to be effectively protect the portions B1 and B2 from the probe needle 74 (to be described later in detail). In FIG. 9, the width of the portions B1 and B2 in the X direction is the width of the upper face of the portion B1 in the X direction.

The width PR of the probe needle 74 is, for example, 10 μm or larger. The width PR of the present embodiment is 10 μm or longer and 20 μm or shorter and is, for example, 12 μm to 20 μm. The width of the portions B1 and B2 of the interconnect 54a in the X direction is, for example, shorter than 10 μm.

In the following, the semiconductor device of the first embodiment is compared with a semiconductor device of a first comparative example of the first embodiment.

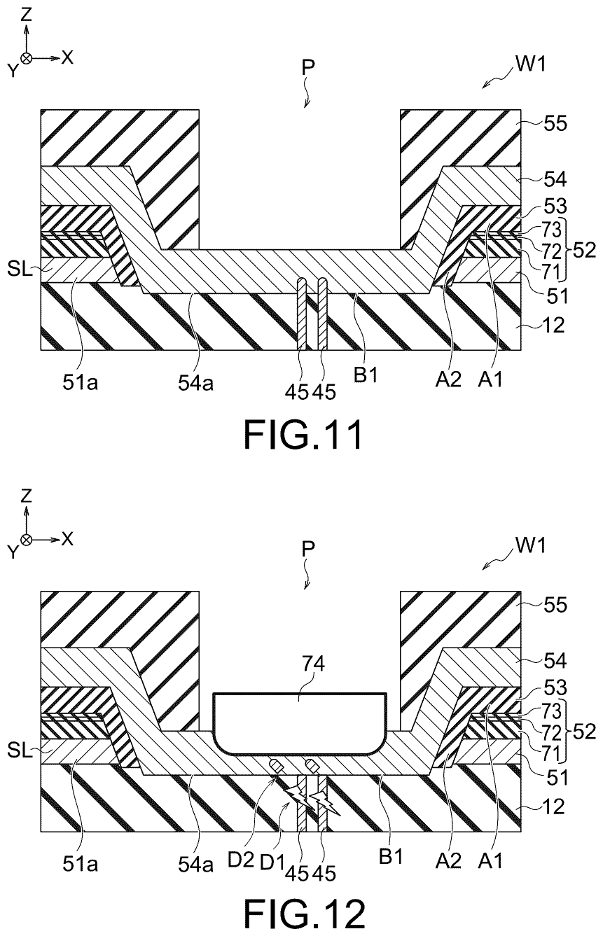

FIGS. 11 and 12 are cross-sectional views illustrating a method of manufacturing the semiconductor device of the first comparative example of the first embodiment. FIGS. 11 and 12 correspond to FIGS. 8 and 9, respectively.

First, the interconnect layer 51, the insulator 52, the insulator 53, the interconnect layer 54, and the passivation insulator 55 are formed on the inter layer dielectric 12 (FIG. 11). The insulator 53 of the present comparative example includes the regions A1 and A2 but not the region A3. In the present comparative example, the interconnect 54a includes the portion B1 but not the portions B2, and the height of the upper end of each via plug 45 is higher than the height of the lower face of the portion B1. Accordingly, the upper portions of the via plugs 45 protrude inside the interconnect 54a.

Subsequently, the interconnect 54a (bonding pad) is contacted with the probe needle 74 to examine the semiconductor device of the present comparative example (FIG. 12). In this case, the via plugs are damaged by pressure from the probe needle 74 in some cases. For example, cracks occur to the via plugs 45 as illustrated with an arrow D1, or the upper portions of the via plugs 45 become defective as illustrated with an arrow D2, in some cases.

However, the insulator 53 of the present embodiment includes the regions A1 to A3 (FIG. 8). Moreover, in the present embodiment, the interconnect 54a includes the portions B1 and B2, and the height of the upper end of each via plug 45 is lower than the height of the lower face of the portion B1 (FIG. 8). This makes it possible to prevent cracks from occurring to the via plugs 45 and the upper portions of the via plugs 45 from becoming defective (FIG. 9). The first reason is that the region A3 can prevent the probe needle 74 from excessively approaching the via plugs 45. The second reason is that the upper portions of the via plugs 45 are unlikely to become defective since the upper portions of the via plugs 45 do not protrude inside the interconnect 54a.

As described above, the width PR of the probe needle 74 of the present embodiment in the X direction is longer than the width of the portions B1 and B2 of the interconnect 54a in the X direction. As a result, when the probe needle 74 approaches the via plugs 45, the lower face of the probe needle 74 contacts the upper face of the region A3. This makes it possible to prevent, with the region A3, the probe needle 74 from excessively approaching the via plugs 45. Since the width PR of the probe needle 74 is longer than the width of the portions B1 and B2, the probe needle 74 contacts the region A3 when the position of the probe needle 74 is misaligned in the X direction.

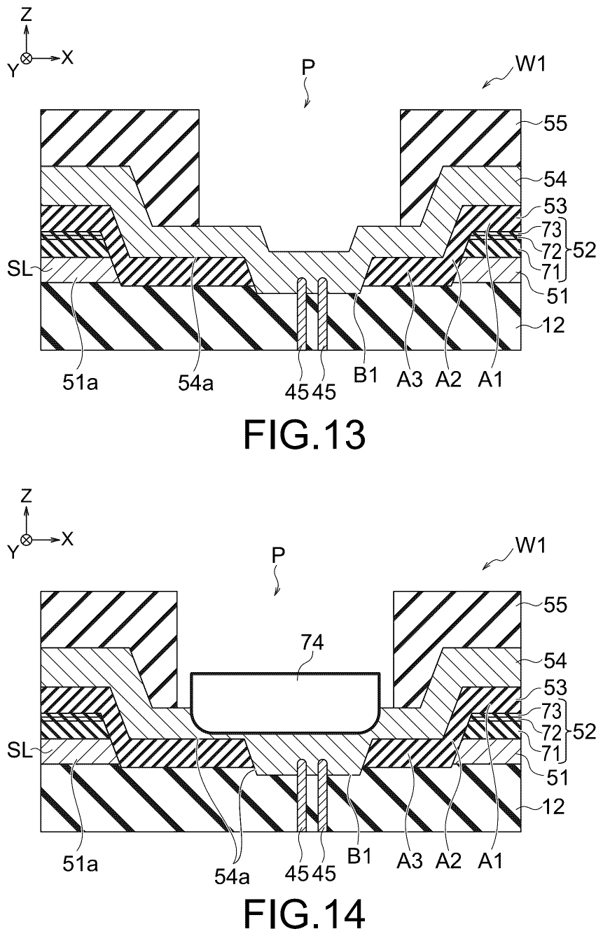

FIGS. 13 and 14 are cross-sectional views illustrating a method of manufacturing the semiconductor device of a first modification of the first embodiment. FIGS. 11 and 12 correspond to FIGS. 8 and 9, respectively.

First, the interconnect layer 51, the insulator 52, the insulator 53, the interconnect layer 54, and the passivation insulator 55 are formed on the inter layer dielectric 12 (FIG. 13). The insulator 53 of the present modification includes the regions A1 to A3. This is the same as in the first embodiment. However, in the present modification, the interconnect 54a includes the portion B1 but not the portions B2, and the height of the upper end of each via plug 45 is higher than the height of the lower face of the portion B1. Accordingly, the upper portions of the via plugs 45 protrude inside the interconnect 54a. This is the same as in the first comparative example.

The present modification makes it possible to prevent cracks from occurring to the via plugs 45 and the upper portions of the via plugs from becoming defective (FIG. 14). This is because the region A3 can prevent the probe needle 74 from excessively approaching the via plugs 45. This is the same as in the first embodiment.

The first embodiment makes it possible to further prevent cracks from occurring to the via plugs 45 and the upper portions of the via plugs 45 from becoming defective (FIG. 9). This is because the upper portions of the via plugs 45 are unlikely to become defective since the upper portions of the via plugs 45 do not protrude inside the interconnect 54a.

### [Planar Structure of Device of First Embodiment]

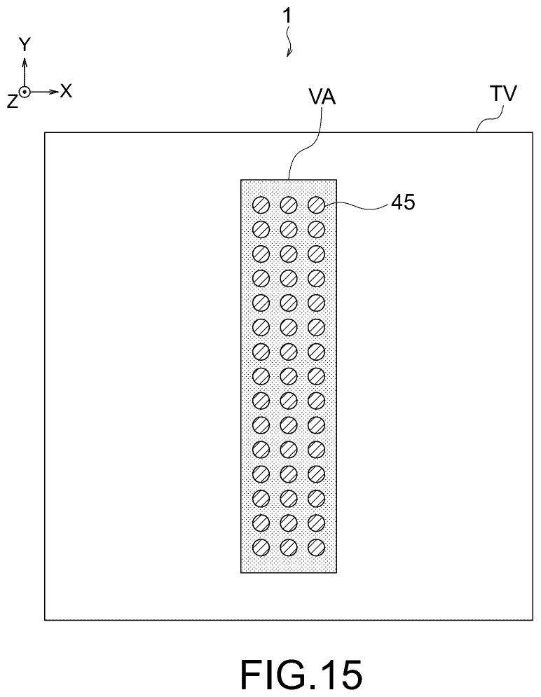

FIG. 15 is a plan view illustrating the structure of the semiconductor device of the first embodiment.

FIG. 15 illustrates the region TV and the region VA illustrated in FIG. 7, and the plurality of via plugs 45 provided below the region VA. The shape of the region TV is approximately square but may be any other shape (for example, rectangle). Similarly, the shape of the region VA is a rectangle extending in the Y direction but may be any other shape (for example, square). The region VA illustrated in FIG. 15 is positioned in the region TV.

In FIG. 15, the number of via plugs 45 is 45 (=3×15) but may be any other number. Since FIG. 7 is an XZ cross-sectional view of the plan view of FIG. 15, the number of via plugs 45 illustrated in FIG. 7 should exactly be three. However, for sake of illustration, only two via plugs 45 are illustrated in FIG. 7.

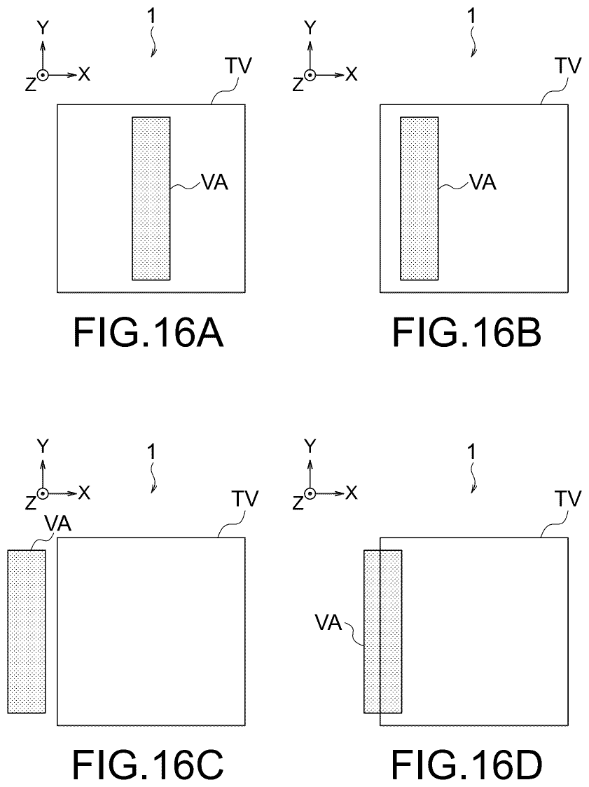

FIGS. 16A to 18D are plan views illustrating various examples of the structure of the semiconductor device of the first embodiment.

As in FIG. 15, FIG. 16A illustrates the region TV and the region VA provided in the region TV. However, FIG. 16A omits illustrations of the via plugs 45 provided below the region VA (similarly hereinafter).

As in FIG. 16A, FIGS. 16B to 16D each illustrate the region TV and the region VA provided in the region TV. However, the region VA in FIG. 16B is disposed near an end portion of the region TV, whereas the region VA in FIG. 16A is disposed near the center of the region TV. The region VA in FIG. 16C is disposed outside the region TV. The region VA in FIG. 16D is disposed partially overlapping the region TV. Accordingly, a portion of the region VA in FIG. 16D is disposed in the region TV, and the rest of the region VA in FIG. 16D is disposed outside the region TV.

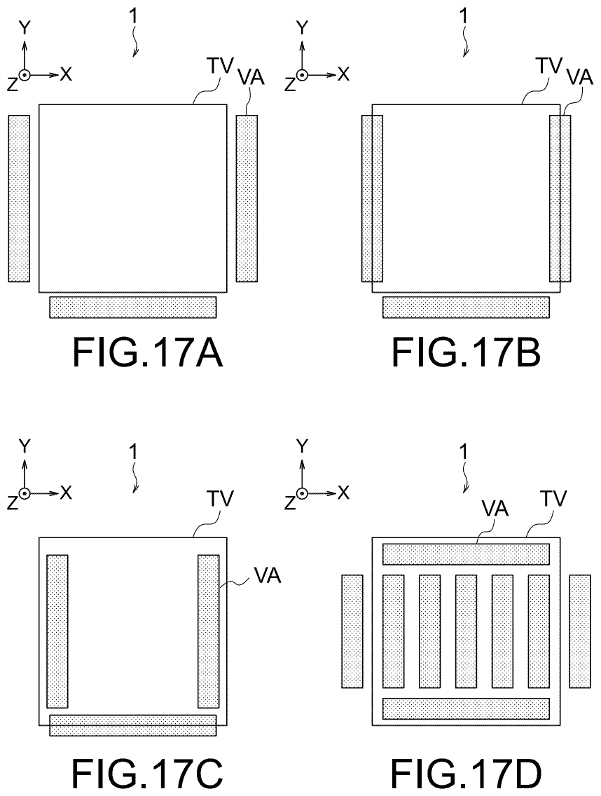

FIGS. 17A to 17D each illustrate the region TV and a plurality of regions VA provided in the region TV. Each region VA is disposed in the region TV, disposed outside the region TV, or disposed partially overlapping the region TV.

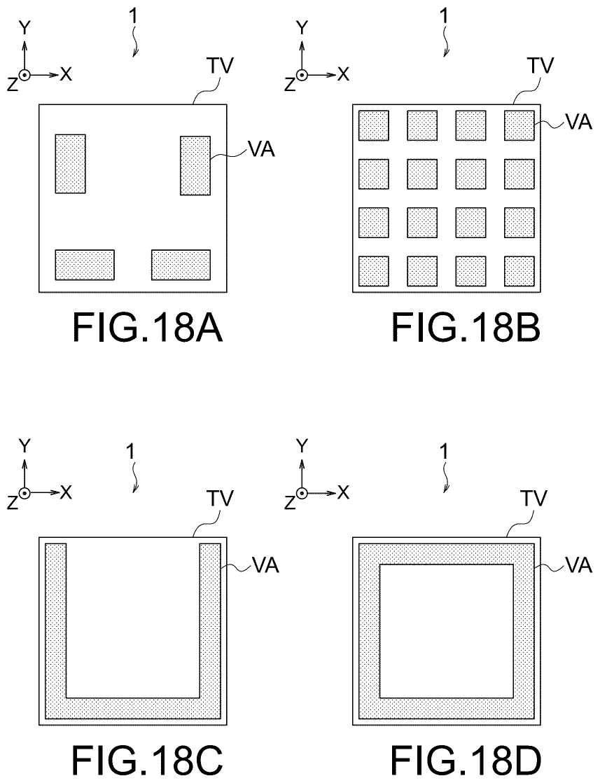

FIGS. 18A to 18D each illustrate the region TV and one or more regions VA provided in the region TV. The regions VA have various shapes. For example, the region VA in FIG. 18C has a shape formed by connecting three rectangles. The region VA in FIG. 18D has a shape formed by connecting four rectangles and has an annular shape.

### [Method of Manufacturing Device of First Embodiment]

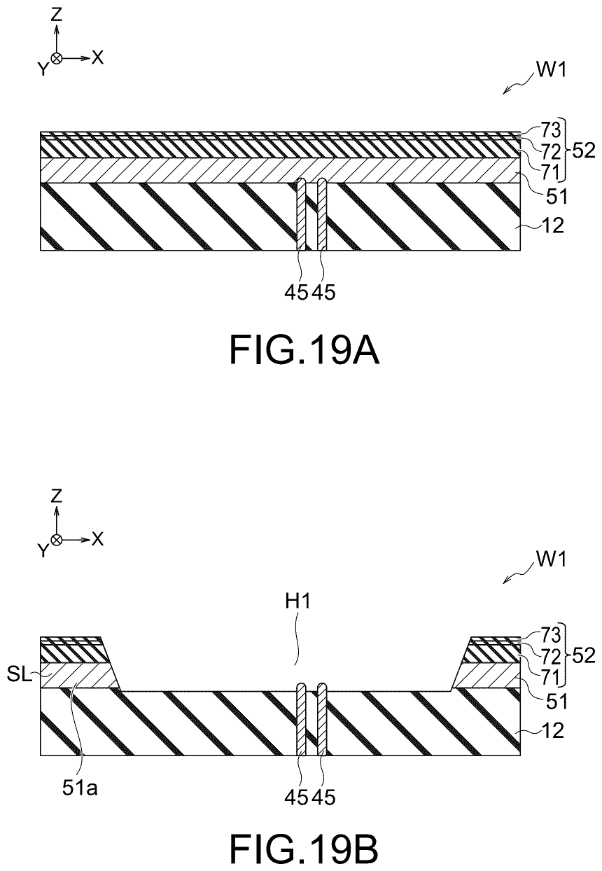

FIGS. 19A to 22B are cross-sectional views illustrating the method of manufacturing the semiconductor device of the first embodiment. FIGS. 19A to 22B illustrate details of the process illustrated in FIG. 8.

First, the interconnect layer 51 and the insulator 52 are sequentially formed on the inter layer dielectric 12 and the via plugs 45 (FIG. 19A). The insulator 52 is formed by sequentially forming the insulators 71, 72, and 73 on the interconnect layer 51. The via plugs 45 are formed in the inter layer dielectric 12 before the array wafer W1 and the circuit wafer W2 are bonded (refer to FIG. 3). In FIG. 19A, the height of the upper end of each via plug 45 is higher than the height of the upper face of the inter layer dielectric 12 (the lower face of the interconnect layer 51).

Subsequently, a concave portion H1 is formed in the insulator 52 and the interconnect layer 51 by lithography and reactive ion etching (RIE) (FIG. 19B). As a result, the upper ends of the via plugs 45 are exposed at the concave portion H1. In addition, the interconnect 51a (source line SL) is formed in the interconnect layer 51. The shape of the above-described region BA is determined by the shape of the concave portion H1. The concave portion H1 is an example of a first concave portion.

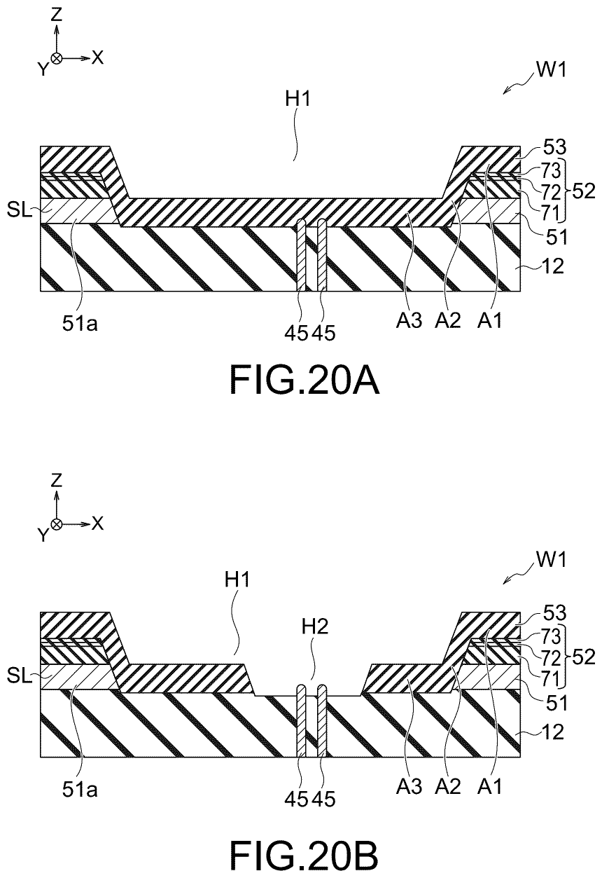

Subsequently, the insulator 53 is formed on the inter layer dielectric 12, the via plugs 45, the interconnect layer 51, and the insulator 52 (FIG. 20A). As a result, the upper ends of the via plugs 45 are covered by the insulator 53. The insulator 53 is formed to include the regions A1, A2, and A3.

Subsequently, a concave portion H2 is formed in the insulator 53 by lithography and RIE (FIG. 20B). As a result, the upper ends of the via plugs 45 are exposed at the concave portion H2. In addition, the region A3 of the insulator 53 is partially removed and processed into the shape illustrated in FIG. 7. The shape of the above-described region VA is determined by the shape of the concave portion H2. The concave portion H2 is an example of a second concave portion.

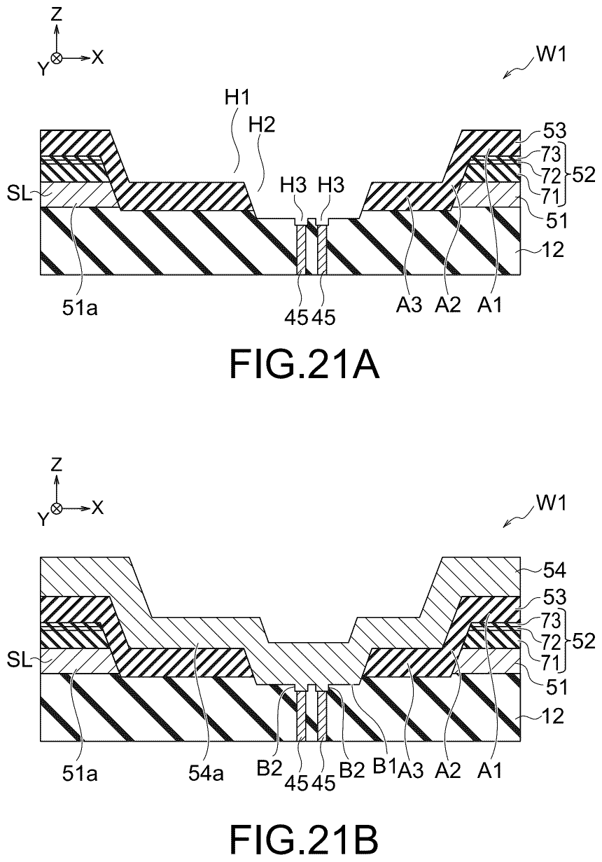

Subsequently, exposed portions of the via plugs 45 and an exposed face of the inter layer dielectric 12 in the concave portion H2 are processed by etching (FIG. 21A). As a result, the height of the upper end of each via plug 45 and the height of the upper face of the inter layer dielectric 12 in the concave portion H2 become lower than before the etching. In the present embodiment, the via plugs 45 outside the inter layer dielectric 12 are removed, and further, the via plugs in the inter layer dielectric 12 are partially removed. As a result, a concave portion H3 is formed in the inter layer dielectric 12 near each via plug 45 and the upper end of the via plug 45 is lowered to a bottom portion of the concave portion H3. FIG. 21A illustrates the left concave portion H3 formed on the left via plug 45, and the right concave portion H3 formed on the right via plug 45. Each concave portion H3 is an example of a third concave portion. Further details of the process in FIG. 21A will be described later.

Subsequently, the interconnect layer 54 is formed on the inter layer dielectric 12, the via plugs 45, the interconnect layer 51, the insulator 52, and the insulator 53, and the interconnect layer 54 is processed by lithography and RIE (FIG. 21B). As a result, the upper ends of the via plugs 45 are covered by the interconnect layer 54. The interconnect layer 54 is formed and processed to include the interconnect 54a. The interconnect 54a illustrated in FIG. 21B includes a portion (first portion) formed on the inter layer dielectric 12 and the via plugs 45, a portion (second portion) formed on the region A3 of the insulator 53, and a portion (third portion) formed on the region A1 of the insulator 53. The portion of the interconnect 54a on the inter layer dielectric 12 and the via plugs 45 includes the portion B1 provided on the inter layer dielectric 12 and the plurality of portions B2 protruding downward from the portion B1. The portion B1 is formed in the concave portion H2, and the portions B2 are formed in the concave portions H3.

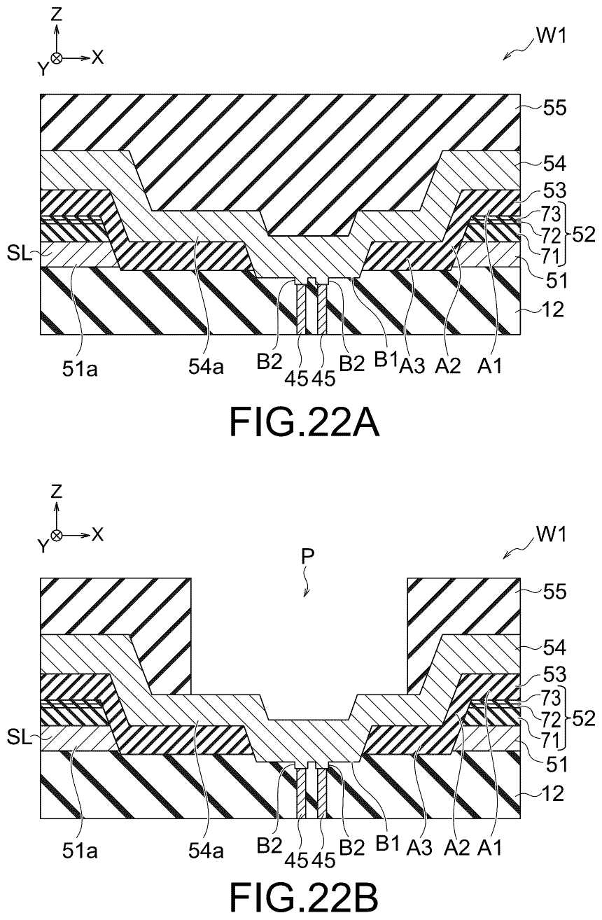

Subsequently, the passivation insulator 55 is formed on the interconnect layer 54 (FIG. 22A), and the passivation insulator 55 is processed by lithography and RIE (FIG. 22B). As a result, the opening P is formed in the passivation insulator 55, and an exposed portion of the interconnect 54a at the opening P becomes the bonding pad.

In the following, the method of manufacturing the semiconductor device of the first embodiment is compared with a method of manufacturing the semiconductor device of the first comparative example of the first embodiment.

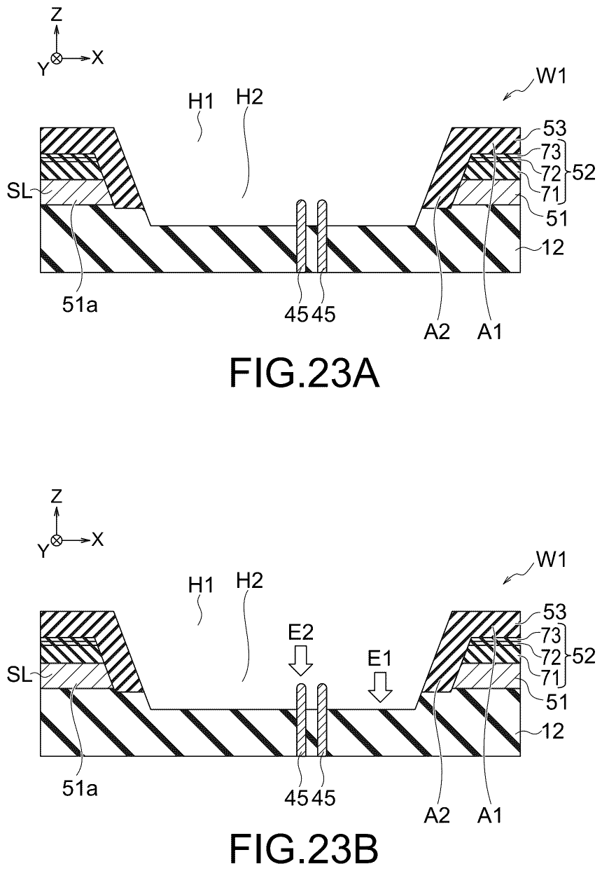

FIGS. 23A and 23B are cross-sectional views illustrating the method of manufacturing the semiconductor device of the first comparative example of the first embodiment.

FIG. 23A corresponds to FIG. 20B. In the present comparative example, exposed portions of the via plugs 45 and an exposed face of the inter layer dielectric 12 in the concave portion H2 are processed by etching (FIG. 23B). As a result, the height of the upper end of each via plug 45 and the height of the upper face of the inter layer dielectric 12 in the concave portion H2 become lower than before the etching.

In FIG. 23B, lowering distance of the upper face of the inter layer dielectric 12 is indicated with an arrow E1, and lowering distance of the upper ends of the via plugs 45 is indicated with an arrow E2. The above-described etching of the present comparative example is performed so that the lowering distance E1 of the upper face of the inter layer dielectric 12 and the lowering distance E2 of the upper ends of the via plugs 45 become substantially equal to each other. Thus, the height of the upper end of each via plug 45 in FIG. 23B is higher than the height of the upper face of the inter layer dielectric 12 near the via plug 45 as in FIG. 23A. Specifically, the difference between the height of the upper end of each via plug 45 and the height of the upper face of the inter layer dielectric 12 near the via plug 45 is substantially equal between FIGS. 23A and 23B. The above-described etching of the present comparative example is, for example, RIE.

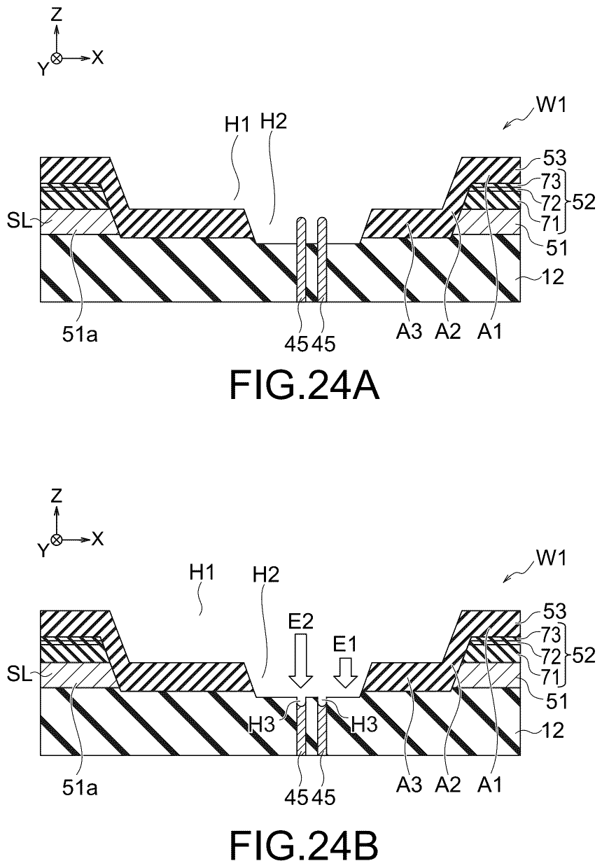

FIGS. 24A and 24B are cross-sectional views illustrating the method of manufacturing the semiconductor device of the first embodiment.

FIG. 24A corresponds to FIG. 20B. In the present embodiment, exposed portions of the via plugs 45 and an exposed face of the inter layer dielectric 12 in the concave portion H2 are processed by etching (FIG. 24B). As a result, the height of the upper end of each via plug 45 and the height of the upper face of the inter layer dielectric 12 in the concave portion H2 become lower than before the etching. FIG. 24B corresponds to FIG. 21A.

In FIG. 24B as well, the lowering distance of the upper face of the inter layer dielectric 12 is indicated with an arrow E1, and the lowering distance of the upper ends of the via plugs 45 is indicated with an arrow E2. The above-described etching of the present embodiment is performed so that the lowering distance E2 of the upper ends of the via plugs 45 becomes longer than the lowering distance E1 of the upper face of the inter layer dielectric 12. Thus, the height of the upper end of each via plug 45 in FIG. 24B is lower than the height of the upper face of the inter layer dielectric 12 near the via plug 45. An example of the above-described etching of the present embodiment will be described later.

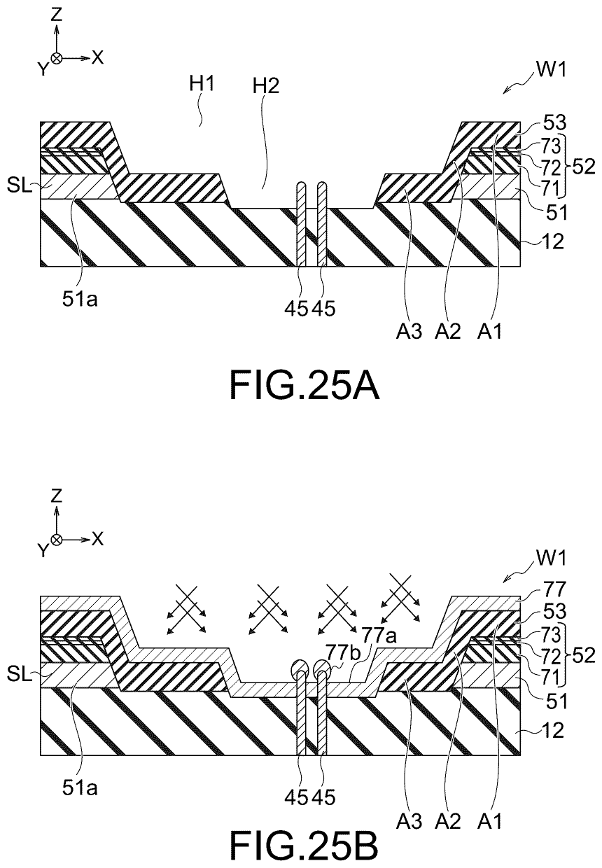

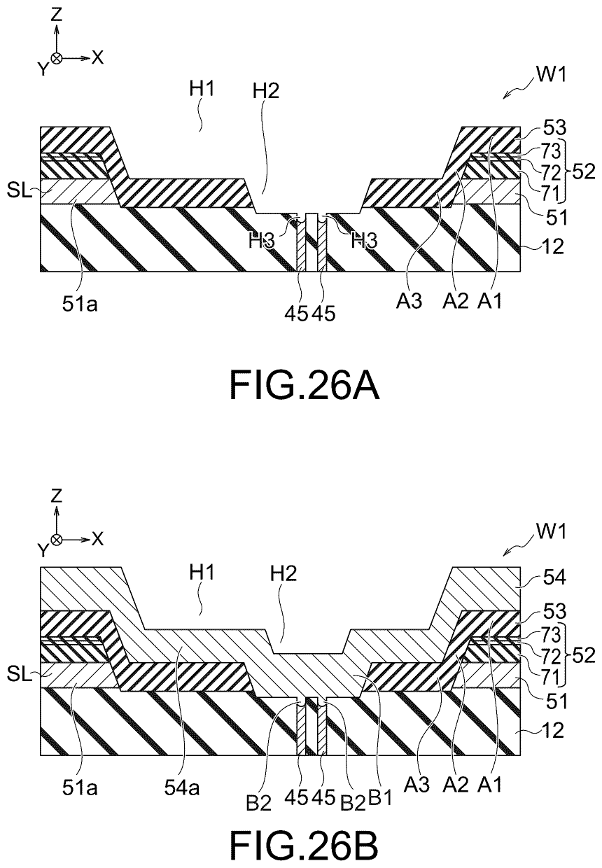

FIGS. 25A to 26B are cross-sectional views illustrating a first example of the method of manufacturing the semiconductor device of the first embodiment.

FIG. 25A corresponds to FIG. 20B. In this example, first, a sacrifice film 77 is formed on the inter layer dielectric 12, the via plugs 45, the interconnect layer 51, the insulator 52, and the insulator 53 (FIG. 25B). The sacrifice film 77 is, for example, a metal film formed by physical vapor deposition (PVD). The sacrifice film 77 is formed to include a portion 77a and a portion 77b, the portion 77a being formed on the surfaces of the inter layer dielectric 12, the interconnect layer 51, the insulator 52, and the insulator 53, the portion 77b being formed near the upper end of each via plug 45. In FIG. 25B, a portion of each via plug 45 is exposed between the portion 77a and the portion 77b. The sacrifice film 77 is an example of a first film.

Subsequently, the sacrifice film 77 and the via plug 45 are processed by isotropic etching (FIG. 25B). The isotropic etching is performed by simultaneously introducing etchant gas and an ion beam into a chamber in which the array wafer W1 and the circuit wafer W2 are housed. As illustrated with arrows in FIG. 25B, the ion beam is introduced into the chamber to travel in a direction tilted relative to the surface of the substrate 14 (XY plane). Thus, the ion beam is incident on the exposed portion of each via plug 45 in an oblique direction (direction tilted relative to the XY plane). Accordingly, the exposed portion of each via plug 45 is etched in the lateral direction from a side face of the via plug 45 by the ion beam. Simultaneously, the sacrifice film 77 is etched by the etchant gas and the ion beam. In a case where the sacrifice film 77 remains after the isotropic etching ends, the remaining the sacrifice film 77 is removed.

FIG. 26A illustrates the array wafer W1 after the isotropic etching ends. The above-described isotropic etching is performed in a state where the surface of the inter layer dielectric 12 is covered by the sacrifice film 77. Accordingly, the isotropic etching can be performed so that the lowering distance E2 of the upper ends of the via plugs 45 becomes longer than the lowering distance E1 of the upper face of the inter layer dielectric 12 (refer to FIG. 24B). As a result, the concave portion H3 is formed in the inter layer dielectric 12 near each via plug 45 and the upper end of the via plug 45 is lowered to a bottom portion of the concave portion H3. FIG. 26A corresponds to FIG. 21A.

Subsequently, the interconnect layer 54 is formed on the inter layer dielectric 12, the via plugs 45, the interconnect layer 51, the insulator 52, and the insulator 53, and the interconnect layer 54 is processed by lithography and RIE (FIG. 26B). As a result, the upper ends of the via plugs 45 are covered by the interconnect layer 54. FIG. 26B corresponds to FIG. 21B.

Thereafter, the processes in FIGS. 22A and 22B are performed. In addition, the processes illustrated in FIGS. 9 and 10 are performed. As a result, a semiconductor device having the structure illustrated in FIG. 7 is manufactured.

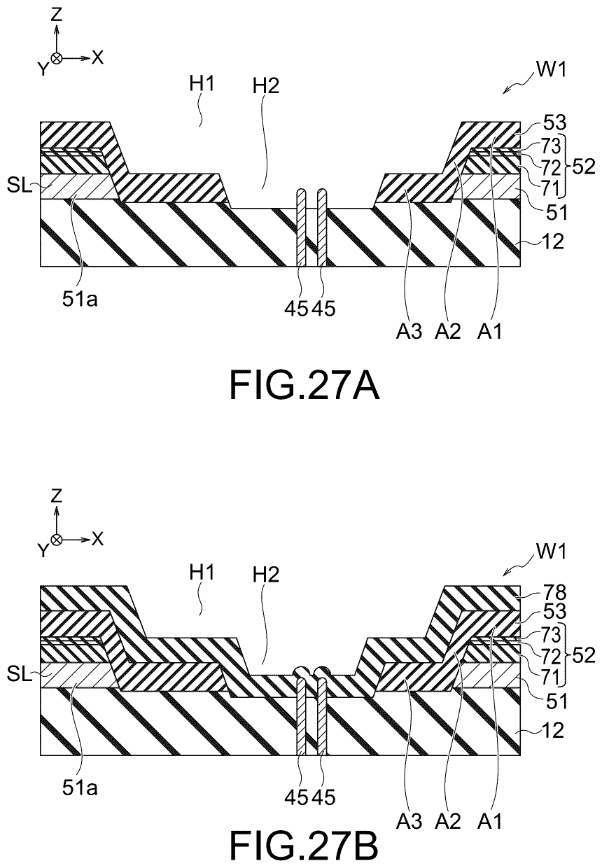

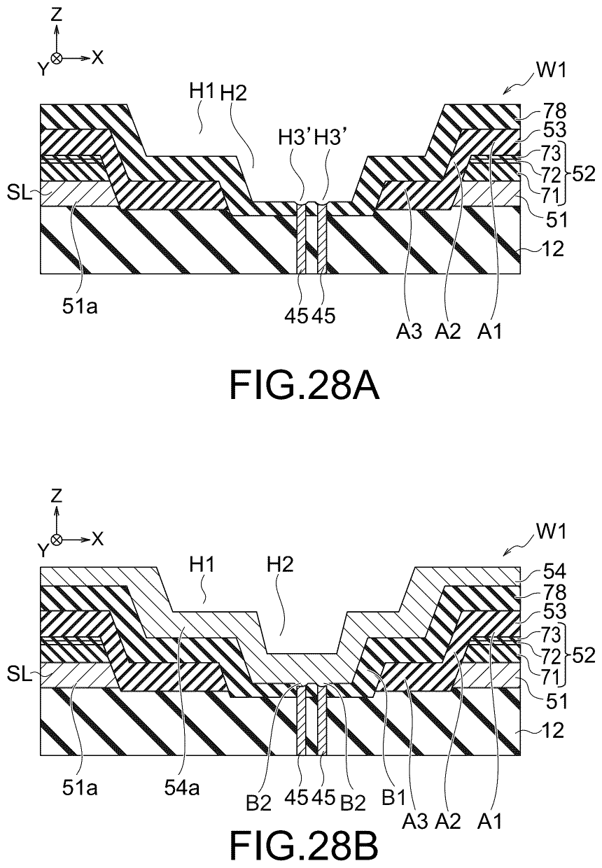

FIGS. 27A to 28B are cross-sectional views illustrating a second example of the method of manufacturing the semiconductor device of the first embodiment.

FIG. 27A corresponds to FIG. 20B. In this example, first, an insulator 78 is formed on the inter layer dielectric 12, the via plugs 45, the interconnect layer 51, the insulator 52, and the insulator 53 (FIG. 27B). The insulator 78 is, for example, a SiO₂ film formed by chemical vapor deposition (CVD). The insulator 78 is formed to cover each via plug 45. Accordingly, each via plug 45 illustrated in FIG. 27B is buried in the inter layer dielectric 12 and the insulator 78. The insulator 78 is an example of a third insulator.

Subsequently, the insulator 78 is processed by RIE etching-back (FIG. 28A). As a result, the insulator 78 is thinned by the etching and the upper end of each via plug 45 is exposed from the insulator 78. In addition, a concave portion H3′ is formed in the insulator 78 near each via plug 45 and the upper end of the via plug 45 is lowered to a bottom portion of the concave portion H3′. In FIG. 28A, the height of the upper end of each via plug 45 is lower than the height of the upper face of the insulator 78 outside the concave portion H3′ and higher than the height of the upper face of the inter layer dielectric 12 near the via plug 45. The concave portion H3′ is an example of a fourth concave portion.

Subsequently, the interconnect layer 54 is formed on the via plugs 45 and the insulator 78, and the interconnect layer 54 is processed by lithography and RIE (FIG. 28B). As a result, the upper ends of the via plugs 45 is covered by the interconnect layer 54. The interconnect layer 54 is formed and processed to include the interconnect 54a. The interconnect 54a illustrated in FIG. 28B is formed on the inter layer dielectric 12 via the insulator 78 and includes a portion (first portion) formed on the via plugs 45, a portion (second portion) formed on the region A3 of the insulator 53 via the insulator 78, and a portion (third portion) formed on the region A1 of the insulator 53 via the insulator 78. The above-described first portion includes the portion B1 provided on the inter layer dielectric 12 via the insulator 78, and the plurality of portions B2 protruding downward from the portion B1. In FIG. 28B, the portion B1 is formed in the concave portion H2, and the portions B2 are formed in the concave portions H3′.

Thereafter, the processes in FIGS. 22A and 22B are performed. In addition, the processes illustrated in FIGS. 9 and 10 are performed. As a result, a semiconductor device having the structure illustrated in FIG. 7 to which the insulator 78 is added is manufactured.

### [Devices of Modifications of First Embodiment]

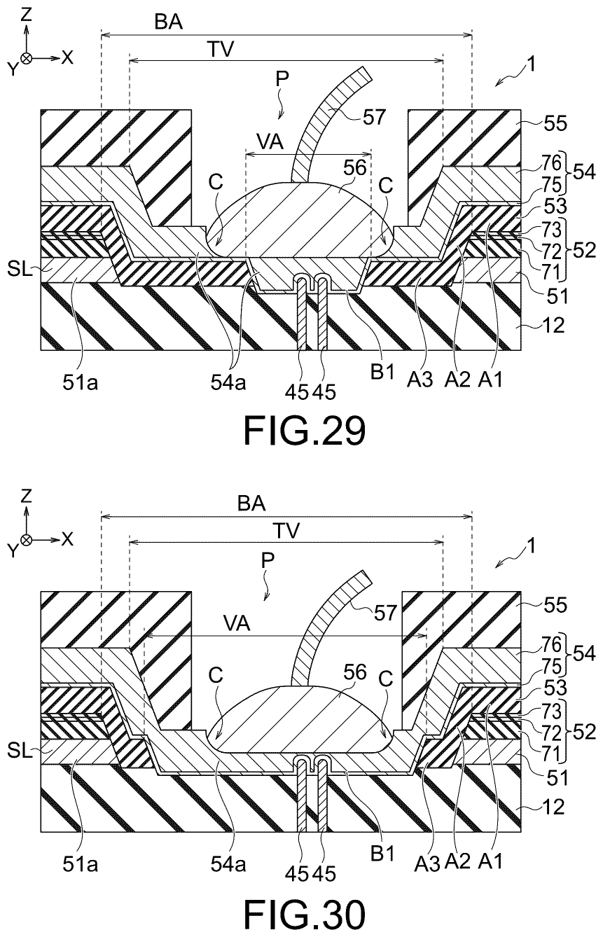

FIG. 29 is a cross-sectional view illustrating the structure of a semiconductor device of a second modification of the first embodiment.

The semiconductor device of the present modification has the same structure as the semiconductor device illustrated in FIG. 7. However, the height of the upper end of each via plug 45 of the present modification is higher than the height of the lower face of the portion B1 of the interconnect 54a. Accordingly, the interconnect 54a of the present modification includes no portions B2.

The interconnect layer 54 of the present modification includes a metal layer 75 and a metal layer 76, the metal layer 75 being formed on the inter layer dielectric 12, the via plugs 45, the interconnect layer 51, the insulator 52, and the insulator 53, the metal layer 76 being formed on the metal layer 75. The metal layer 76 is formed of a material different from the material of the metal layer 75. The metal layer 75 is, for example, a multilayer film including a W layer, a titanium nitride (TiN) layer, and a titanium (Ti) layer. The metal layer 76 is, for example, an Al layer. The metal layers 75 and 76 are examples of first and second layers, respectively.

The present modification makes it possible to prevent cracks from occurring to the via plugs 45 and the upper portions of the via plugs from becoming defective. The first reason is that the region A3 can prevent the probe needle 74 (refer to FIG. 9) from excessively approaching the via plugs 45. The second reason is that the upper portions of the via plugs 45 are unlikely to become defective since the upper portions of the via plugs 45 are protected by the metal layer 75. In a case where the metal layer 75 includes a W layer, the Young's modulus of the W layer is high, and thus the upper portions of the via plugs 45 can be effectively protected by the metal layer 75.

The semiconductor device of the present modification can be manufactured by, for example, the method illustrated in FIGS. 13 and 14. Through the process illustrated in FIG. 13, the interconnect layer 54 is formed in a state where the upper ends of the via plugs 45 are higher than the bottom face of the concave portion H2 (the upper face of the inter layer dielectric 12 near the via plugs 45). In this case, the interconnect layer 54 of the present modification is formed by sequentially forming the metal layers 75 and 76. Accordingly, the structure illustrated in FIG. 29 is achieved.

FIG. 30 is a cross-sectional view illustrating the structure of a semiconductor device of a third modification of the first embodiment.

The semiconductor device of the present modification has the same structure as the semiconductor device of the second modification illustrated in FIG. 29. However, the width of the portion B1 of the interconnect 54a of the present modification in the X direction is longer than the width PR of the probe needle 74 in the X direction, whereas the width of the portion B1 of the interconnect 54a of the second modification in the X direction is shorter than the width PR of the probe needle 74 in the X direction (refer to FIG. 9). The region A3 of the present modification is disposed at a position not overlapping the opening P in plan view, whereas the region A3 of the second modification is disposed at a position partially overlapping the opening P in plan view.

For the above-described first and second reasons, the second modification makes it possible to prevent cracks from occurring to the via plugs 45 and the upper portions of the via plugs 45 from becoming defective. For the above-described second reason, the present modification makes it possible to prevent cracks from occurring to the via plugs 45 and the upper portions of the via plugs 45 from becoming defective.

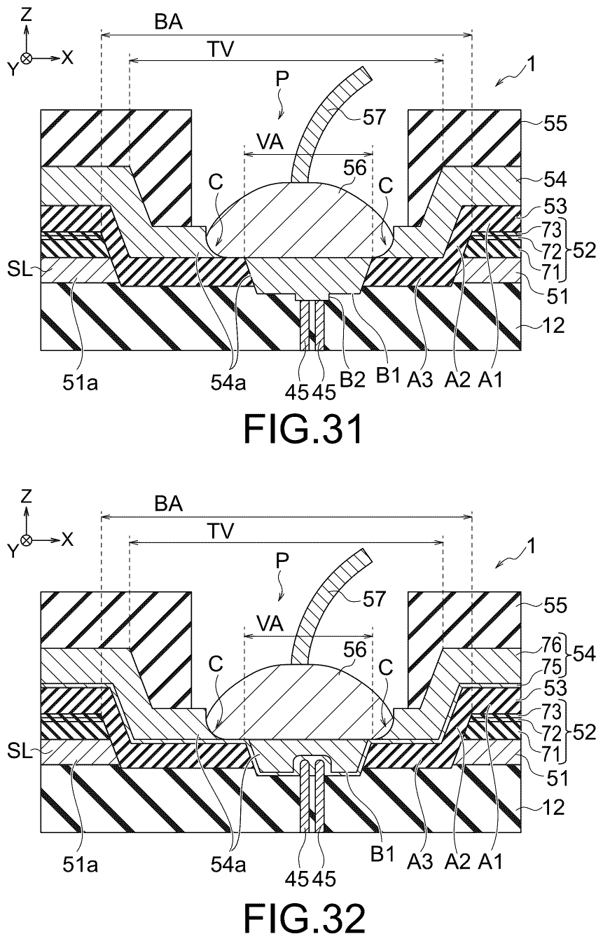

FIG. 31 is a cross-sectional view illustrating the structure of a semiconductor device of a fourth modification of the first embodiment.

The semiconductor device of the present modification has the same structure as the semiconductor device illustrated in FIG. 7. However, the interconnect 54a of the present modification includes one portion B2 on the plurality of via plugs 45. In other words, the portion B2 illustrated in FIG. 31 is shared by the left via plug 45 and the right via plug 45. With the portion B2 of the present modification, it is possible to obtain the same effects as with the portions B2 illustrated in FIG. 7.

FIG. 32 is a cross-sectional view illustrating the structure of a semiconductor device of a fifth modification of the first embodiment.

The semiconductor device of the present modification has the same structure as the semiconductor device of the second modification illustrated in FIG. 29. However, the metal layer 75 of the present modification collectively covers the upper portions of the plurality of via plugs 45, whereas the metal layer 75 of the second modification individually covers the upper portions of the plurality of via plugs 45. Accordingly, FIG. 32 illustrates one protrusion portion of the metal layer 75, whereas FIG. 29 illustrates two protrusion portions of the metal layer 75. With the interconnect 54a of the present modification, it is possible to obtain the same effects as with the interconnect 54a of the second modification.

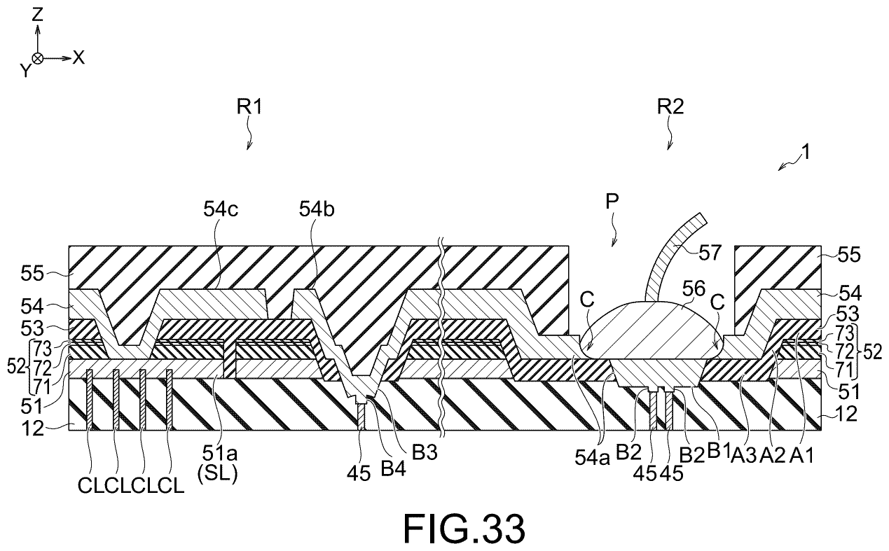

FIG. 33 is a cross-sectional view illustrating the structure of a semiconductor device of a sixth modification of the first embodiment.

FIG. 33 illustrates an array region R1 and a pad region R2 included in the semiconductor device of the present modification. The array region R1 includes the memory cell array 11 (refer to FIG. 1), and the pad region R2 includes the interconnect 54a that functions as a bonding pad. The pad region R2 illustrated in FIG. 33 has the same structure as the section illustrated in FIG. 7. However, the interconnect 51a (source line SL) of the present modification is not disposed near the interconnect 54a but is disposed in the array region R1. FIG. 33 illustrates the plurality of columnar portions CL disposed below the interconnect 51a in the array region R1.

The interconnect layer 54 of the present modification includes the interconnect 54a included in the pad region R2, and interconnects 54b and 54c included in the array region R1. The interconnect 54b is formed on the inter layer dielectric 12, the via plugs 45, and the insulator 53 and electrically connected to the via plugs 45. The interconnect 54c is formed on the interconnect 51a, the insulator 52, and the insulator 53 and electrically connected to the interconnect 51a.

The interconnect 54b includes a portion B3 having the same shape as the portion B1 of the interconnect 54a, and a portion B4 having the same shape as each portion B2 of the interconnect 54a. The portion B3 is provided on the inter layer dielectric 12. The portion B4 protrudes downward from the portion B3 and is provided on the via plugs 45. However, the interconnect 54b is not exposed at the opening P of the passivation insulator 55 and does not function as a bonding pad.

With the interconnect 54a in the pad region R2 of the present modification, it is possible to obtain the same effects as with the interconnect 54a illustrated in FIG. 7.

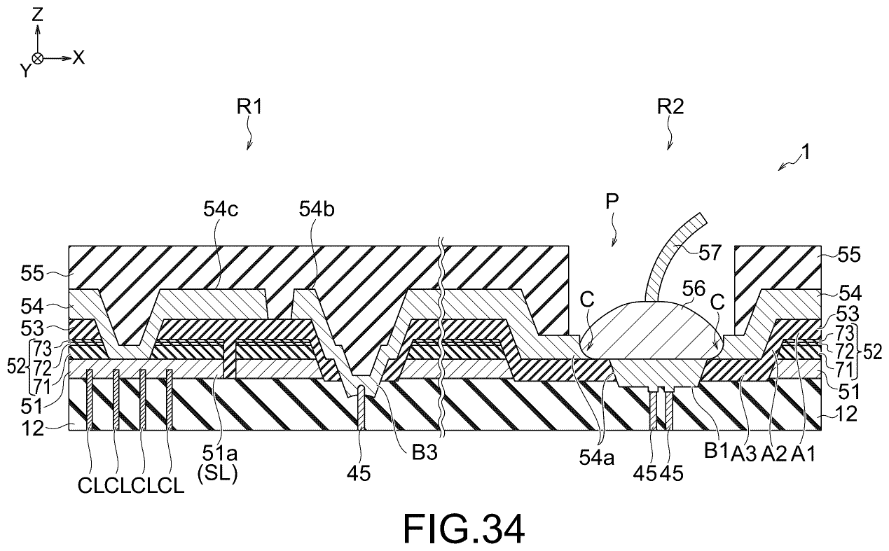

FIG. 34 is a cross-sectional view illustrating the structure of a semiconductor device of a seventh modification of the first embodiment.

The semiconductor device of the present modification has the same structure as the semiconductor device of the sixth modification illustrated in FIG. 33. However, the interconnect 54b of the present modification has a structure including the portion B3 but not the portion B4. In other words, the interconnect 54b of the present modification has the same structure as the interconnect 54a illustrated in FIG. 13, which includes the portion B1 but not the portions B2.

In the present modification, the interconnect 54a functions as a bonding pad, but the interconnect 54b does not function a bonding pad. Thus, such examination as illustrated in FIG. 9 is not performed for the interconnect 54b. Thus, the interconnect 54b may be formed not to include the portion B4 as in the present modification.

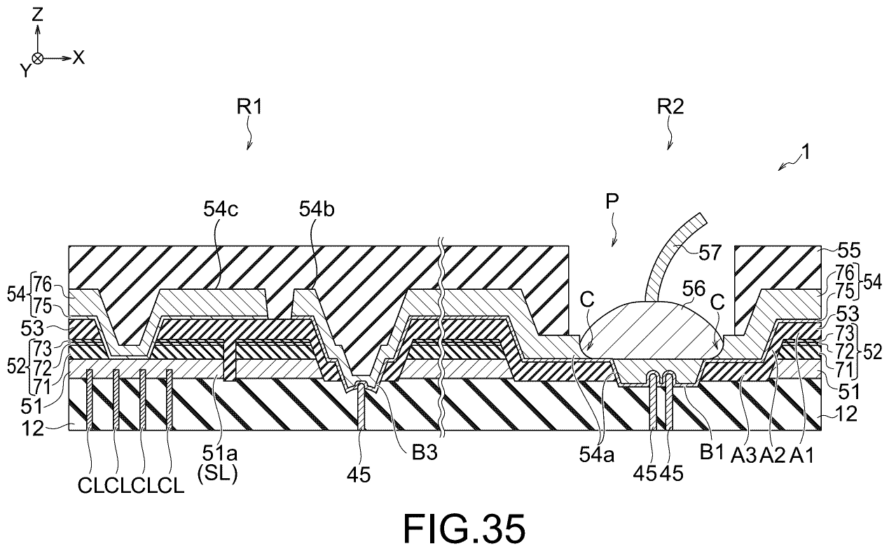

FIG. 35 is a cross-sectional view illustrating the structure of a semiconductor device of an eighth modification of the first embodiment.

The semiconductor device of the present modification has the same structure as the semiconductor device of the sixth modification illustrated in FIG. 33. However, the interconnect layer 54 of the present modification includes the metal layers 75 and 76. In the present modification, the interconnect 54a includes the portion B1 but not the portions B2, and the interconnect 54b includes the portion B3 but not the portion B4. In other words, the interconnects 54a and 54b of the present modification have the same structure as the interconnect 54a illustrated in FIG. 29.

With the interconnect 54a in the pad region R2 of the present modification, it is possible to obtain the same effects as with the interconnect 54a illustrated in FIG. 29.

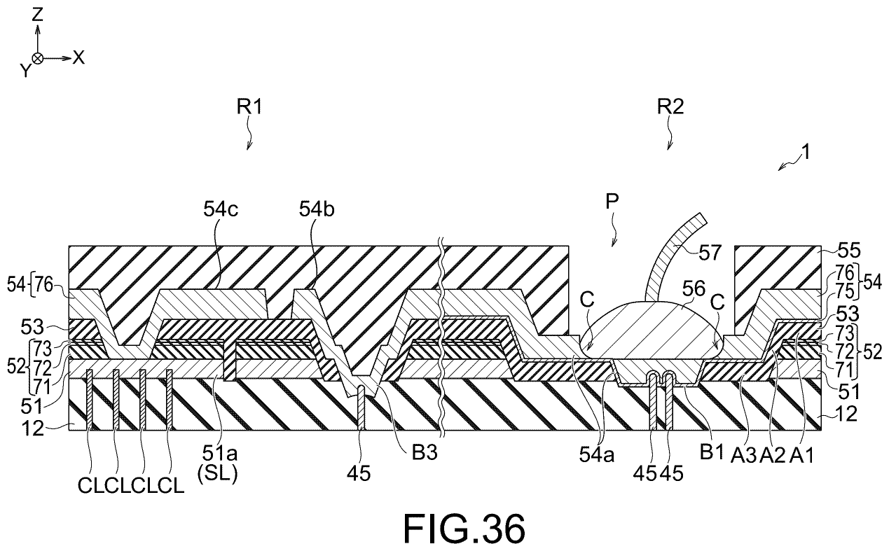

FIG. 36 is a cross-sectional view illustrating the structure of a semiconductor device of a ninth modification of the first embodiment.

The semiconductor device of the present modification has the same structure as the semiconductor device of the eighth modification illustrated in FIG. 35. However, the interconnect layer 54 of the present modification includes the metal layers 75 and 76 in the pad region R2 but includes only the metal layer 76 in the array region R1. Accordingly, in the present modification, the interconnect 54a includes the metal layers 75 and 76, but the interconnects 54b and 54c include only the metal layer 76.

In the present modification, the interconnect 54a functions as a bonding pad, but the interconnect 54b does not function a bonding pad. Thus, such examination as illustrated in FIG. 9 is not performed for the interconnect 54b. Thus, the interconnect 54b may be formed not to include the metal layer 75 as in the present modification.

As described above, the semiconductor device of the present embodiment includes the insulator 53 and the interconnect layer 54, the insulator 53 including the regions A1 to A3, the interconnect layer 54 being provided on the insulator 53 and the via plugs 45 and including a bonding pad. Thus, the present embodiment makes it possible to form preferable via plugs 45. For example, it is possible to prevent the via plugs 45 from being damaged when the bonding pad is contacted with the probe needle 74.

### Second Embodiment

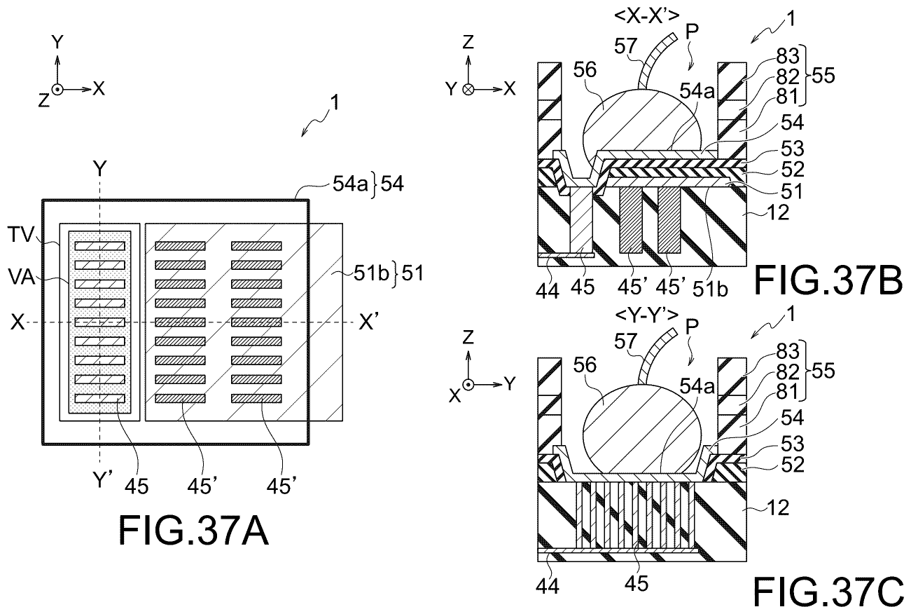

FIGS. 37A to 37C are plan views and a cross-sectional view illustrating the structure of a semiconductor device of a second embodiment.

The semiconductor device of the present embodiment has a structure similar to that of the semiconductor device illustrated in FIG. 7. FIG. 37A illustrates a planar structure of the semiconductor device of the present embodiment. FIG. 37B illustrates an XZ section along line X-X′ illustrated in FIG. 37A. FIG. 37C illustrates a YZ section along line Y-Y′ illustrated in FIG. 37A.

As illustrated in FIGS. 37B and 37C, the semiconductor device of the present embodiment includes the inter layer dielectric 12, the plurality of via plugs 45, the interconnect layer 51, the insulator 52, the insulator 53, the interconnect layer 54, the passivation insulator 55, the solder 56, and the bonding wire 57. The passivation insulator 55 includes an insulator 81, an insulator 82, and an insulator 83 formed in order on the insulator 53 and the interconnect layer 54.

In FIGS. 37B and 37C, the interconnect layer 54 includes the interconnect 54a including a bonding pad, and the interconnect layer 51 includes an interconnect 51b different from the interconnect 51a (source line SL). The interconnect 51b is provided below the interconnect 54a via the insulators 53 and 52 and is not in contact with the interconnect 54a. FIG. 37A illustrates planar shapes of the region TV, the region VA, the interconnect 51a, and the interconnect 54b.

As illustrated in FIGS. 37A to 37C, the semiconductor device of the present embodiment further includes a plurality of dummy plugs 45′ disposed at the same height as the via plugs 45. Each via plug 45 functions as a plug for controlling the semiconductor device of the present embodiment, but each dummy plug 45′ does not function as a plug for controlling the semiconductor device of the present embodiment. For example, each via plug 45 is used as a plug for supplying power voltage or signal voltage to a device such as the memory cell array 11 or the transistors 31 (refer to FIG. 1), or a plug supplied with signal voltage from the device, but each dummy plug 45′ is not used as such a plug. In FIGS. 37A to 37C, each dummy plug 45′ is electrically connected to no device nor bonding pad in the semiconductor device of the present embodiment. To distinguish the via plugs 45 and the dummy plugs 45′, FIGS. 37A to 37C illustrate the via plugs 45 with coarse hatching and the dummy plugs 45′ with dense hatching. Each dummy plug 45′ is an example of a third plug.

In FIGS. 37B and 37C, the dummy plugs 45′ are provided on the lower face of the interconnect 51b in the inter layer dielectric 12 and electrically connected to the interconnect 51b. Similarly to the dummy plugs 45′, the interconnect 51b is electrically connected to no device nor bonding pad in the semiconductor device of the present embodiment. The dummy plugs 45′ of the present embodiment are formed of the same material as the material of the via plugs 45 simultaneously with the via plugs 45 through the process illustrated in FIG. 3. Accordingly, similarly to the via plugs 45, the dummy plugs 45′ are each, for example, a metal plug including a W layer. In the present embodiment, the via plugs 45 are disposed on the interconnect layer 44, but the dummy plugs 45′ are not disposed on the interconnect layer 44.

FIG. 37A illustrates planar shapes of the via plugs 45 and the dummy plugs 45′. The planar shapes of the via plugs 45 and the dummy plugs 45′ of the present embodiment are rectangles extending in the X direction, whereas the planar shape of the via plugs 45 of the first embodiment is a circle (refer to FIG. 15). However, the via plugs 45 and the dummy plugs 45′ of the present embodiment may have other planar shapes.

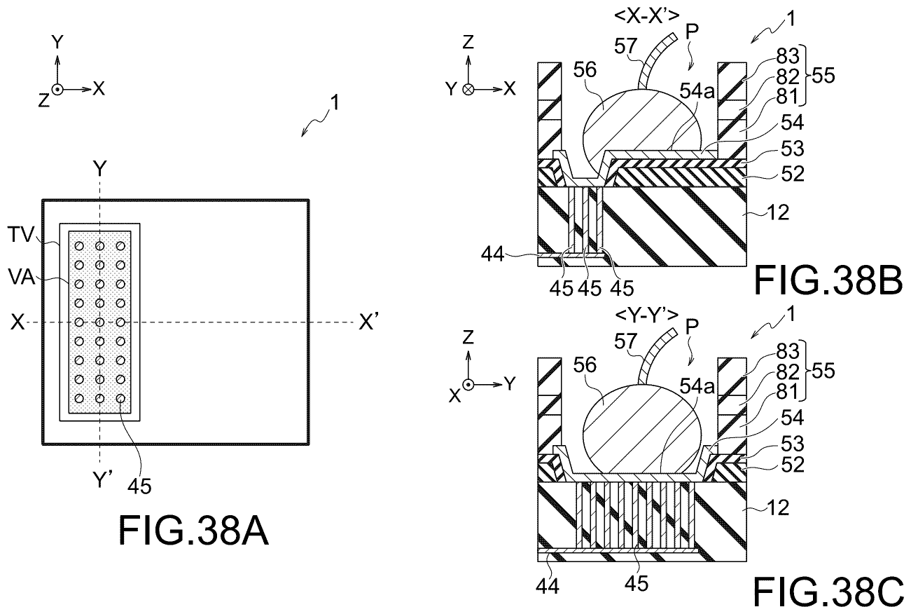

FIGS. 38A to 38C are plan views and a cross-sectional view illustrating the structure of a semiconductor device of a first comparative example of the second embodiment.

FIG. 38A illustrates a planar structure of the semiconductor device of the present comparative example. FIG. 38B illustrates an XZ section along line X-X′ illustrated in FIG. 38A. FIG. 38C illustrates a YZ section along line Y-Y′ illustrated in FIG. 38A.

The semiconductor device of the present comparative example has the same structure as the semiconductor device of the second embodiment. However, the semiconductor device of the present comparative example includes no dummy plugs 45′ nor interconnect 54b. The planar shape of each via plug 45 of the present comparative example is a circle.

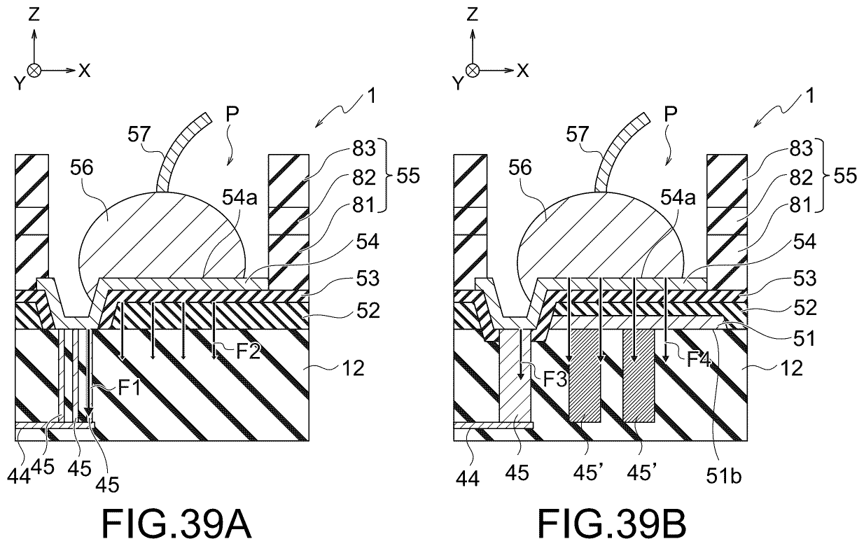

FIGS. 39A and 39B are cross-sectional views for comparing the semiconductor device of the second embodiment and the first comparative example of the semiconductor device of the second embodiment.

As in FIG. 38B, FIG. 39A illustrates an XZ section of the first comparative example of the semiconductor device of the second embodiment. FIG. 39A illustrates stress F1 applied to the interconnect 54a in the region TV and stress F2 applied to the interconnect 54a outside the region TV. The stress applied to the interconnect 54a is likely to concentrate in a region in which a hard layer exists below the interconnect 54a. The interconnect 54a in the region TV is disposed on the via plugs 45 as a hard layer. Accordingly, in FIG. 39A, the large stress F1 is likely to be applied to the interconnect 54a in the region TV. As a result, the via plugs 45 are potentially damaged. Large stress is likely to be applied to the interconnect 54a when the interconnect 54a is contacted with the probe needle 74 or when the bonding wire 57 is disposed on the interconnect 54a.

As in FIG. 37B, FIG. 39B illustrates an XZ section of the semiconductor device of the second embodiment. FIG. 39B illustrates stress F3 applied to the interconnect 54a in the region TV and stress F4 applied to the interconnect 54a outside the region TV. In FIG. 39B, the interconnect 54a in the region TV is disposed on the via plugs 45 as a hard layer, and the interconnect 54a outside the region TV is disposed above the interconnect 51b and the dummy plugs 45′ as a hard layer. Accordingly, in FIG. 39B, the large stress F3 is unlikely to be applied to the interconnect 54a in the region TV. This is because stress applied to the interconnect 54a is distributed between the stress F3 and the stress F4. This makes it possible to prevent the via plugs 45 from being damaged.

[Devices of Modifications of Second Embodiment]

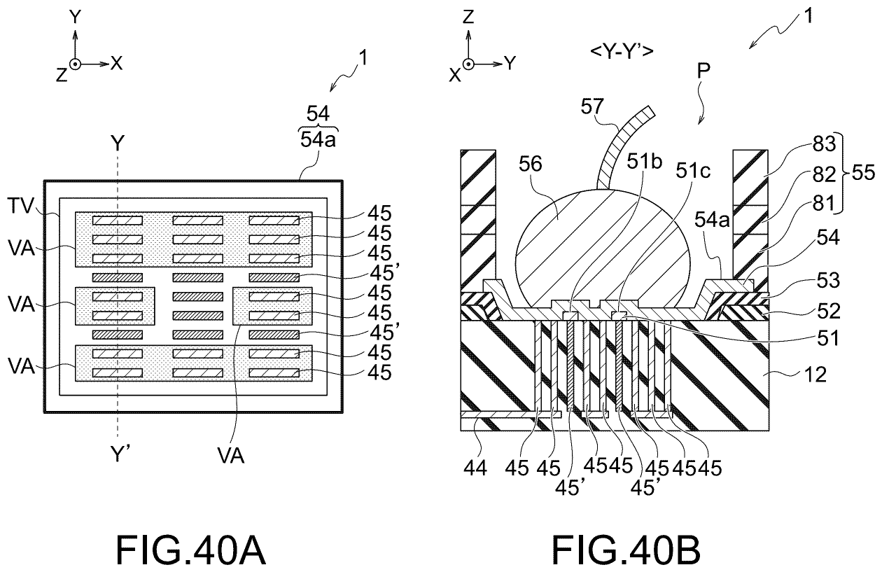

FIGS. 40A and 40B are a plan view and a cross-sectional view illustrating the structure of a semiconductor device of a first modification of the second embodiment. FIG. 40A illustrates a planar structure of the semiconductor device of the present modification. FIG. 40B illustrates a YZ section along line Y-Y′ illustrated in FIG. 40A.

The semiconductor device of the present modification has the same structure as the semiconductor device of the second embodiment. However, the interconnect layer 51 of the present modification includes interconnects 51b and 51c provided on the lower face of the interconnect 54a. The interconnects 51b and 51c of the present modification are in contact with the interconnect 54a and electrically connected to the interconnect 54a. FIG. 40B illustrates the dummy plugs 45′ provided on the lower face of the interconnect 51b and the dummy plugs 45′ provided on the lower face of the interconnect 51c.

Each dummy plug 45′ of the second embodiment is electrically connected to no device nor bonding pad in the semiconductor device. However, each dummy plug 45′ of the present modification is electrically connected to a device or a bonding pad in the semiconductor device. Specifically, each dummy plug 45′ of the present modification is electrically connected to the interconnect 54a (bonding pad) through the interconnects 51b and 51c and electrically connected to devices such as the memory cell array 11 and the transistors 31 through the via plugs 45. However, each dummy plug 45′ of the present modification does not function as a plug for controlling the semiconductor device of the present modification. This is because power voltage or signal voltage supplied to a device from the interconnect 54a is not supplied to the device through the dummy plugs 45′ but is supplied to the device through the via plugs 45. This is the same for signal voltage supplied to the interconnect 54a from the device.

With the interconnects 51b and 51c and the dummy plugs 45′ of the present modification, it is possible to obtain the same effects as with the interconnect 51b and the dummy plugs 45′ of the second embodiment. Each dummy plug 45′ of the present modification may be disposed on the interconnect layer 44 as long as the interconnect 54a is not electrically connected to a device through the dummy plug 45′. This is the same for modifications to be described later. For the same reason, each dummy plug 45′ of the second embodiment may be disposed on the interconnect layer 44.

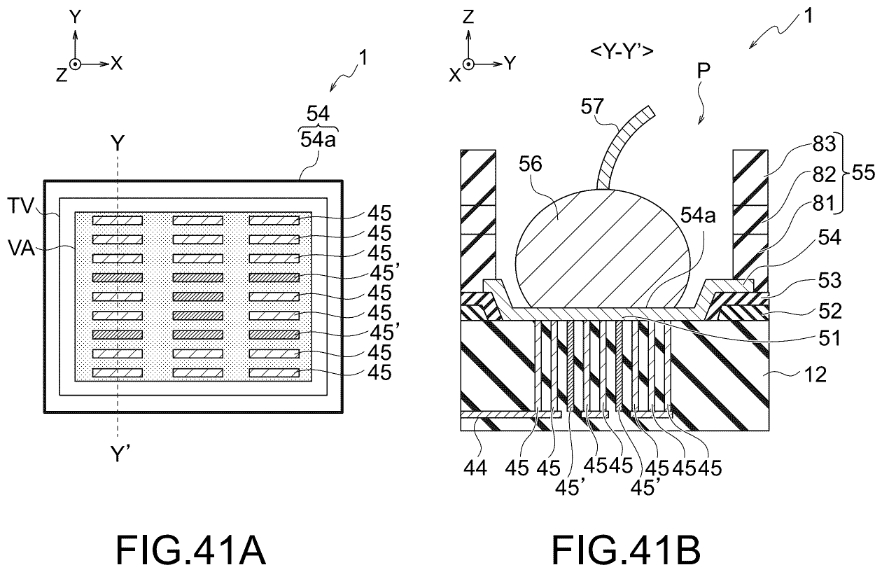

FIGS. 41A and 41B are a plan view and a cross-sectional view illustrating the structure of the semiconductor device of a second modification of the second embodiment. FIG. 41A illustrates a planar structure of the semiconductor device of the present modification. FIG. 41B illustrates a YZ section along line Y-Y′ illustrated in FIG. 41A.

The semiconductor device of the present modification has the same structure as the semiconductor device of the second embodiment. However, the interconnect layer 51 of the present modification includes no interconnect 51b. FIG. 41B illustrates the plurality of dummy plugs 45′ provided on the lower face of the interconnect 54a. The dummy plugs 45′ are in contact with the interconnect 54a and electrically connected to the interconnect 54a. With the dummy plugs 45′ of the present modification, it is possible to obtain the same effects as with the interconnect 51b and the dummy plugs 45′ of the second embodiment.

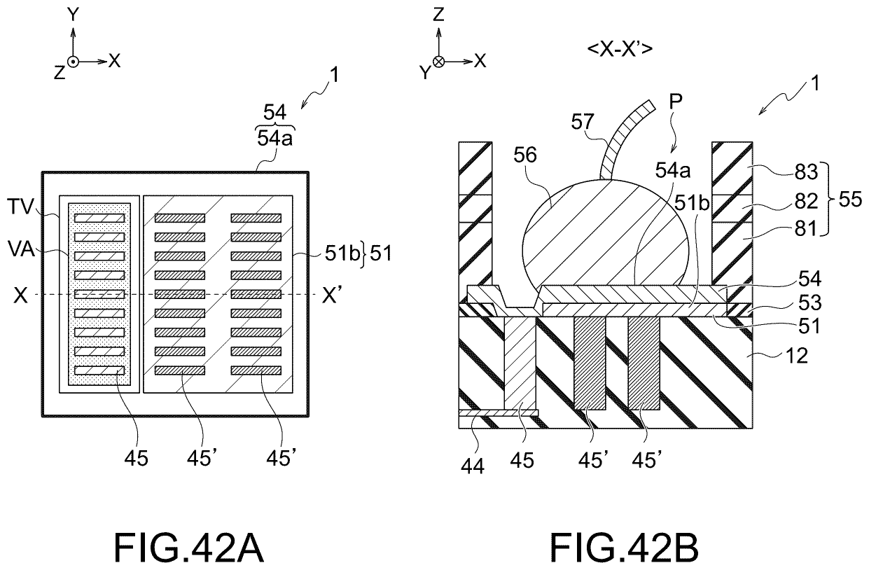

FIGS. 42A and 42B are a plan view and a cross-sectional view illustrating the structure of a semiconductor device of a third modification of the second embodiment. FIG. 42A illustrates a planar structure of the semiconductor device of the present modification. FIG. 42B illustrates an XZ section along line X-X′ illustrated in FIG. 42A.

The semiconductor device of the present modification has the same structure as the semiconductor device of the second embodiment. However, the interconnect layer 51 of the present modification includes the interconnect 51b provided in a wide range on the lower face of the interconnect 54a. The interconnect 51b of the present modification is in contact with the interconnect 54a and electrically connected to the interconnect 54a. FIG. 42B illustrates the plurality of dummy plugs 45′ provided on the lower face of the interconnect 51b. With the interconnect 51b and the dummy plugs 45′ of the present modification, it is possible to obtain the same effects as with the interconnect 51b and the dummy plugs 45′ of the second embodiment.

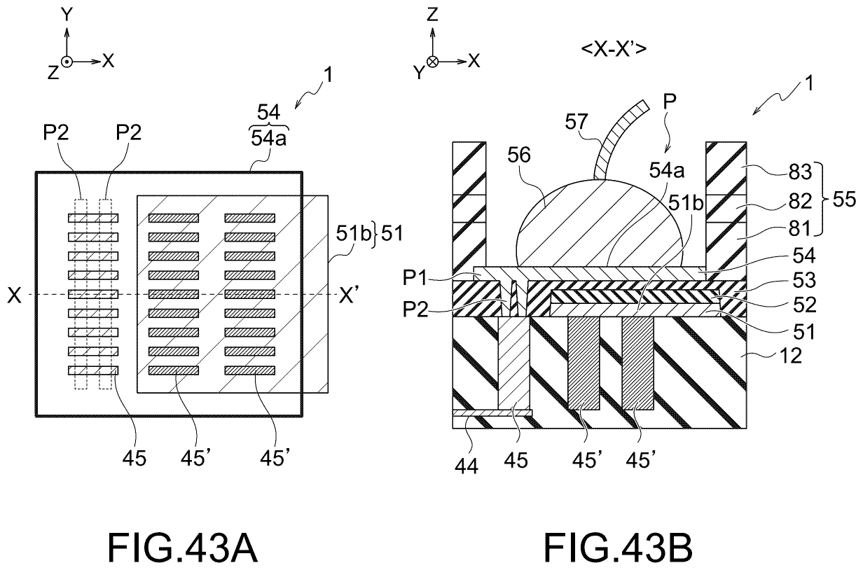

FIGS. 43A and 43B are a plan view and a cross-sectional view illustrating the structure of a semiconductor device of a fourth modification of the second embodiment. FIG. 43A illustrates a planar structure of the semiconductor device of the present modification. FIG. 43B illustrates an XZ section along line X-X′ illustrated in FIG. 43A.

The semiconductor device of the present modification has the same structure as the semiconductor device of the second embodiment. However, the interconnect 54a of the present modification includes a portion P1 having a flat plate shape and a plurality of portions P2 protruding downward from the portion P1. As illustrated in FIGS. 43A and 43B, each portion P2 extends in the Y direction and is disposed on the plurality of via plugs 45. With the interconnect 51b and the dummy plugs 45′ of the present modification, it is possible to obtain the same effects as with the interconnect 51b and the dummy plugs 45′ of the second embodiment.

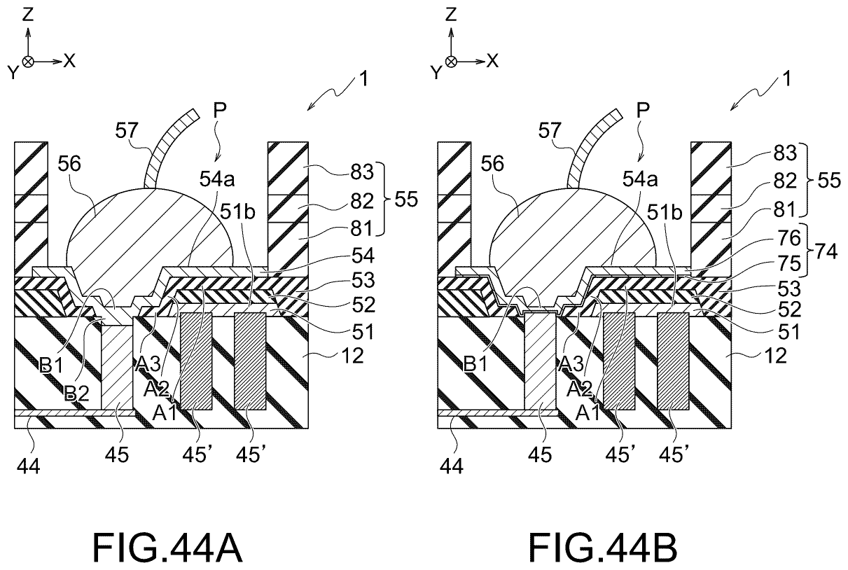

FIGS. 44A and 44B are cross-sectional views illustrating the structures of semiconductor devices of a fifth modification and a sixth modification of the second embodiment.

FIG. 44A illustrates an XZ section of the semiconductor device of the fifth modification of the second embodiment. The semiconductor device of the present modification has the same structure as the semiconductor device of the second embodiment. However, similarly to the interconnect 54a illustrated in FIG. 7, the interconnect 54a of the present modification includes the portions B1 and B2. This makes it possible to obtain the effects of the first embodiment, as well, with the present modification.

FIG. 44B illustrates an XZ section of the semiconductor device of the sixth modification of the second embodiment. The semiconductor device of the present modification has the same structure as the semiconductor device of the second embodiment. However, similarly to the interconnect 54a illustrated in FIG. 29, the interconnect 54a of the present modification includes the metal layers 75 and 76. This makes it possible to obtain the effects of the first embodiment, as well, with the present modification.

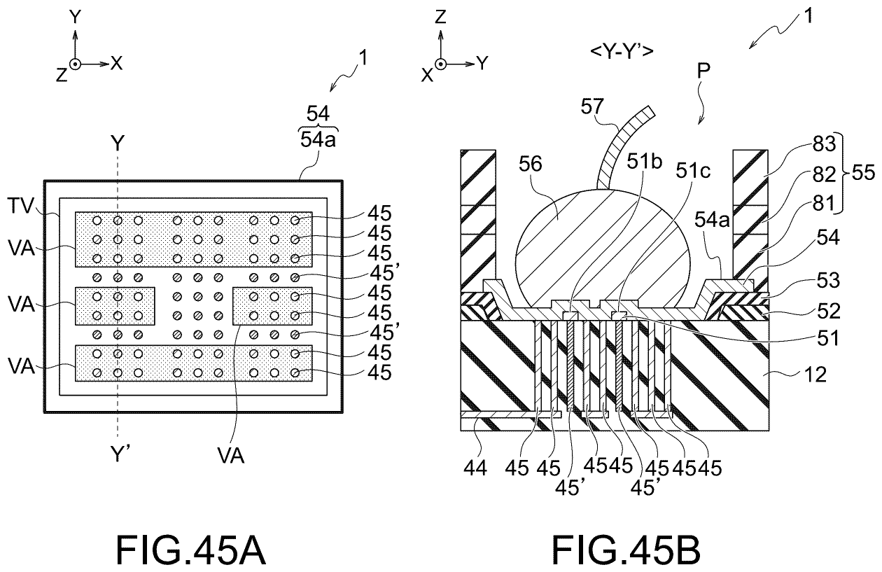

FIGS. 45A and 45B are a plan view and a cross-sectional view illustrating the structure of a semiconductor device of a seventh modification of the second embodiment. FIG. 45A illustrates a planar structure of the semiconductor device of the present modification. FIG. 45B illustrates a YZ section along line Y-Y′ illustrated in FIG. 45A.

The semiconductor device of the present modification has the same structure as the semiconductor device of the first modification of the second embodiment. However, the via plugs 45 and the dummy plugs 45′ of the present modification have circular planar shapes. With the present modification, it is possible to obtain the same effects as with the first modification.

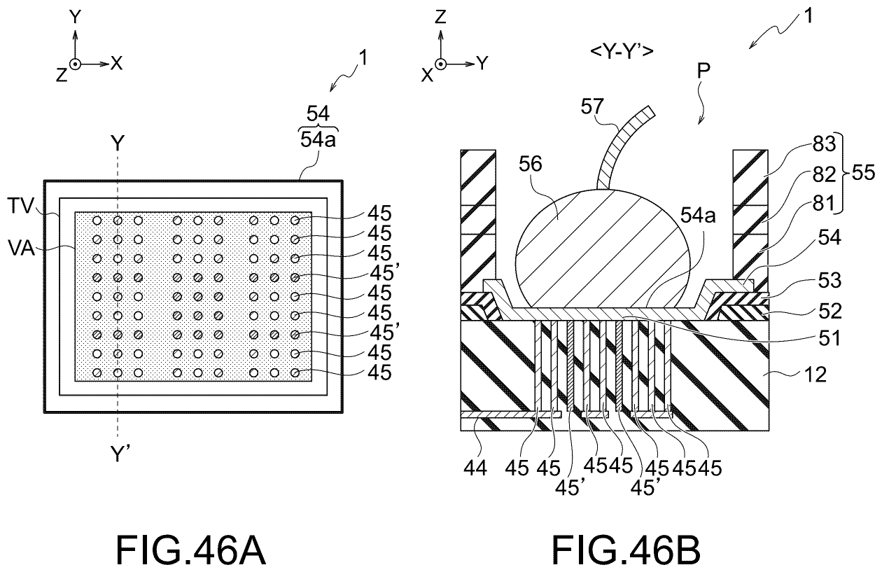

FIGS. 46A and 46B are a plan view and a cross-sectional view illustrating the structure of a semiconductor device of an eighth modification of the second embodiment. FIG. 46A illustrates a planar structure of the semiconductor device of the present modification. FIG. 46B illustrates a YZ section along line Y-Y′ illustrated in FIG. 46A.

The semiconductor device of the present modification has the same structure as the semiconductor device of the second modification of the second embodiment. However, the via plugs 45 and the dummy plugs 45′ of the present modification have circular planar shapes. With the present modification, it is possible to obtain the same effects as with the second modification.

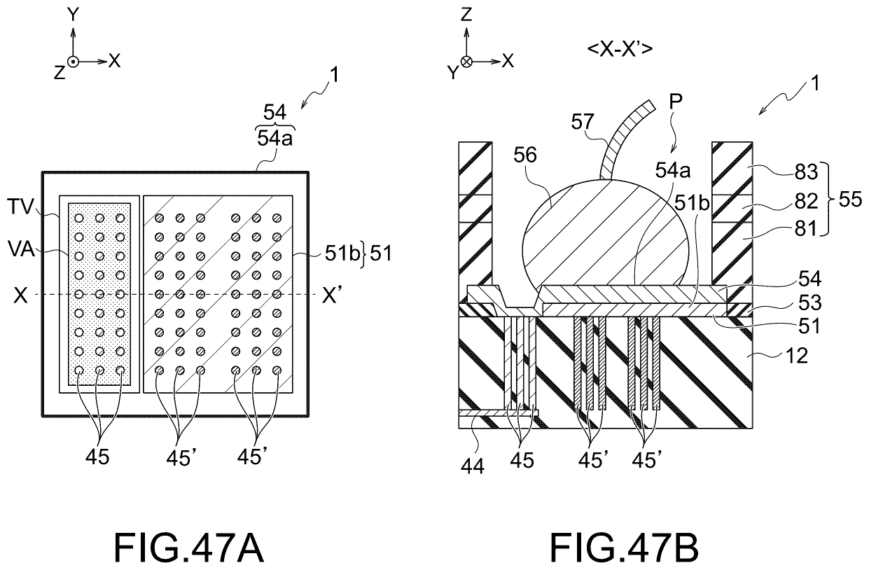

FIGS. 47A and 47B are a plan view and a cross-sectional view illustrating the structure of a semiconductor device of a ninth modification of the second embodiment. FIG. 47A illustrates a planar structure of the semiconductor device of the present modification. FIG. 47B illustrates an XZ section along line X-X′ illustrated in FIG. 47A.

The semiconductor device of the present modification has the same structure as the semiconductor device of the third modification of the second embodiment. However, the via plugs 45 and the dummy plugs 45′ of the present modification have circular planar shapes. With the present modification, it is possible to obtain the same effects as with the third modification.

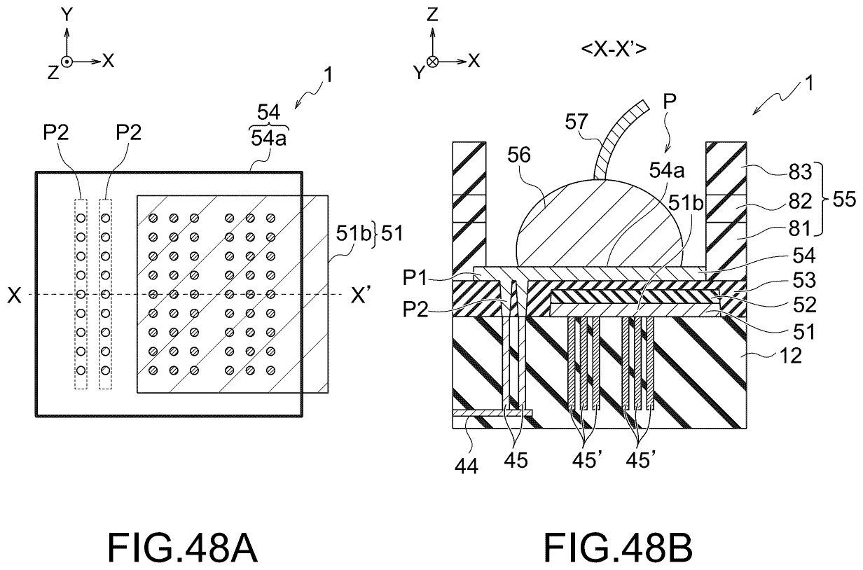

FIGS. 48A and 48B are a plan view and a cross-sectional view illustrating the structure of a semiconductor device of a tenth modification of the second embodiment. FIG. 48A illustrates a planar structure of the semiconductor device of the present modification. FIG. 48B illustrates an XZ section along line X-X′ illustrated in FIG. 48A.

The semiconductor device of the present modification has the same structure as the semiconductor device of the fourth modification of the second embodiment. However, the via plugs 45 and the dummy plugs 45′ of the present modification have circular planar shapes. With the present modification, it is possible to obtain the same effects as with the fourth modification.

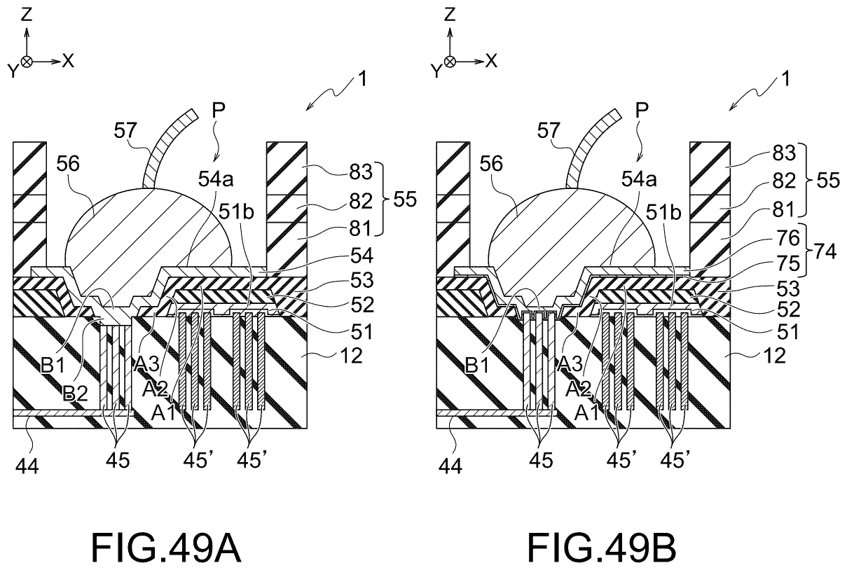

FIGS. 49A and 49B are cross-sectional views illustrating the structures of semiconductor devices of an eleventh modification and a twelfth modification of the second embodiment.

FIG. 49A illustrates an XZ section of the semiconductor device of the eleventh modification of the second embodiment. The semiconductor device of the present modification has the same structure as the semiconductor device of the fifth modification of the second embodiment. However, the via plugs 45 and the dummy plugs 45′ of the present modification have circular planar shapes. With the present modification, it is possible to obtain the same effects as with the fifth modification.

FIG. 49B illustrates an XZ section of the semiconductor device of the twelfth modification of the second embodiment.

The semiconductor device of the present modification has the same structure as the semiconductor device of the sixth modification of the second embodiment. However, the via plugs 45 and the dummy plugs 45′ of the present modification have circular planar shapes. With the present modification, it is possible to obtain the same effects as with the sixth modification.

As described above, the semiconductor device of the present embodiment includes the dummy plugs 45′ below the bonding pad (interconnect 54a). Thus, the present embodiment makes it possible to form preferable via plugs 45. For example, it is possible to prevent the via plugs 45 from being damaged when the interconnect 54a is contacted with the probe needle 74 or when the bonding wire 57 is disposed on the interconnect 54a.

The planar shapes of the via plugs 45 may be circles as described above or may be rectangles or other shapes. The rectangular planar shapes of the via plugs 45 have the advantage that, for example, defects in the via plugs 45 can be more easily prevented compared to the circular planar shapes of the via plugs 45.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a first insulator;
a first plug provided in the first insulator;
a first interconnect layer provided on the first insulator;
a second insulator including a first region that is provided on the first insulator and includes a first upper face, and a second region that is provided on the first interconnect layer and includes a second upper face higher than the first upper face; and
a second interconnect layer including a first portion that is provided on the first insulator and the first plug, a second portion that is provided on the first region, and a third portion that is provided on the second region, the second interconnect layer further including a bonding pad.

2. The device of claim 1, wherein the first portion includes an upper portion that is provided on the first insulator, and a lower portion that protrudes downward from the upper portion and is provided on at least the first plug.

3. The device of claim 2, wherein a height of an upper end of the first plug is lower than a height of a lower face of the upper portion.

4. The device of claim 1, wherein a height of an upper end of the first plug is higher than a height of a lower face of the first portion.

5. The device of claim 4, wherein the second interconnect layer includes a first layer that is provided on the first insulator and the first plug, and a second layer that is provided on the first layer.

6. The device of claim 1, further comprising a second plug provided in the first insulator,
wherein the first portion is provided on the first insulator, the first plug, and the second plug.

7. The device of claim 6, wherein the first portion includes an upper portion that is provided on the first insulator, a first lower portion that protrudes downward from the upper portion and is provided on at least the first plug, and a second lower portion that protrudes downward from the upper portion and is provided on at least the second plug.

8. The device of claim 6, wherein the first portion includes an upper portion that is provided on the first insulator, and a lower portion that protrudes downward from the upper portion and is provided on at least the first plug and the second plug.

9. The device of claim 1, further comprising a third insulator that is provided on the first insulator and the second insulator, and is provided below the second interconnect layer,
wherein
the first plug is provided in the first insulator and the third insulator,
the first portion is provided on the first insulator via the third insulator, and is provided on the first plug, the second portion is provided on the first region via the third insulator, and the third portion is provided on the second region via the third insulator, and
the first portion includes an upper portion that is provided on the first insulator via the third insulator, and a lower portion that protrudes downward from the upper portion and is provided on at least the first plug.

10. The device of claim 1, further comprising a third plug that is provided below the bonding pad and provided on a lower face of the first interconnect layer or the second interconnect layer, and does not function as a plug for controlling the semiconductor device.

11. A method of manufacturing a semiconductor device, comprising:
forming a first insulator;
forming a first plug in the first insulator;
forming a first interconnect layer on the first insulator;
forming a second insulator including a first region that is provided on the first insulator and includes a first upper face, and a second region that is provided on the first interconnect layer and includes a second upper face higher than the first upper face; and
forming a second interconnect layer including a first portion that is provided on the first insulator and the first plug, a second portion that is provided on the first region, a third portion that is provided on the second region, the second interconnect layer further including a bonding pad.

12. The method of claim 11, further comprising forming a first concave portion in the first interconnect layer to expose an upper end of the first plug in the first concave portion,
wherein the second insulator is formed after the first concave portion is formed.

13. The method of claim 12, further comprising forming a second concave portion in the second insulator to expose the upper end of the first plug in the second concave portion,
wherein the second interconnect layer is formed after the second concave portion is formed.

14. The method of claim 13, wherein
after the second concave portion is formed, an exposed portion of the first plug is processed, and a third concave portion is formed in the first insulator, so that the upper end of the first plug is lowered to a bottom portion of the third concave portion, and
the second interconnect layer is formed after the third concave portion is formed.

15. The method of claim 14, wherein the exposed portion of the first plug is processed by isotropic etching.

16. The method of claim 15, wherein the isotropic etching is performed by using etchant gas and an ion beam, after a first film is formed on the first insulator, the second insulator, and the first plug.

17. The method of claim 16, wherein the ion beam is incident on the first plug at a tilt relative to a surface of a first substrate provided with the first insulator.

18. The method of claim 13, further comprising:
forming a third insulator on the first insulator, the second insulator, and the first plug after the second concave portion is formed; and
forming a fourth concave portion in the third insulator to expose the upper end of the first plug at a bottom portion of the fourth concave portion,
wherein the second interconnect layer is formed after the fourth concave portion is formed.

19. The method of claim 13, wherein the second interconnect layer is formed in a state where the upper end of the first plug is higher than a bottom face of the second concave portion.

20. The method of claim 11, further comprising contacting the bonding pad with a probe needle,
wherein a width of the probe needle is larger than a width of the first portion.
